(19) United States
(12) Patent Application Publication
(10) Pub. No.: US 2007/0158826 A1
(43) Pub. Date: Jul. 12, 2007

(54) SEMICONDUCTOR DEVICE

(75) Inventors: Shingo Sakakibara, Hamamatsu-shi (JP); Hiroshi Saitoh, Iwata-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-Shi (JP)

(21) Appl. No.: 11/616,125

(22) Filed: Dec. 26, 2006

(30) Foreign Application Priority Data
Dec. 27, 2005 (JP) P2005-375837
Mar. 28, 2006 (JP) P2006-87942
Jun. 22, 2006 (JP) 2006-172617

(51) Int. Cl. H01L 23/34

(52) U.S. Cl. 257/723

(57) ABSTRACT

A semiconductor device includes a substrate, a semiconductor chip having a diaphragm, which vibrates in response to sound pressure variations, and a circuit chip that is electrically connected to the semiconductor chip so as to control the semiconductor chip, wherein the semiconductor chip is fixed to the surface of the circuit chip whose backside is mounted on the surface of the substrate. Herein, a plurality of connection terminals formed on the backside of the semiconductor chip are electrically connected to a plurality of electrodes running through the circuit chip. A ring-shaped resin sheet is inserted between the semiconductor chip and the circuit chip. The semiconductor chip and the circuit chip vertically joined together are stored in a shield case having a mount member (e.g., a stage) and a cover member, wherein connection terminals of the circuit chip are exposed to the exterior via through holes of the stage.

### BACKGROUND OF THE INVENTION

1. Field of the Invention

The present invention relates to semiconductor devices having semiconductor chips such as pressure sensor chips and sound pressure sensor chips.

This application claims priority on Japanese Patent Applications Nos. 2005-375837, 2006-87942, and 2006-172617, the contents of which are incorporated herein by reference.

2. Description of the Related Art

In semiconductor devices serving as silicon capacitor microphones and pressure sensors, semiconductor chips (e.g., pressure sensor chips and sound pressure sensor chips mounted on substrates) include diaphragms that vibrate in response to pressures applied thereto so as to detect pressure variations such as sound pressure variations. Japanese Patent Application Publication No. 2004-537182 discloses an example of a miniature silicon capacitor microphone. In this type of semiconductor device whose semiconductor chip is mounted on a substrate, a cavity is formed between the diaphragm and the surface of the substrate.

When the cavity has a relatively small volume, an air spring constant thereof increases so as to make it difficult for the diaphragm to vibrate. This reduces the displacement of the diaphragm, thus reducing the accuracy of the detection of pressure variations. That is, it is necessary for the semiconductor device to secure a sufficiently large cavity so as to make it easy for the diaphragm to vibrate. In other words, it is necessary to appropriately change the volume of the cavity in response to characteristics of the semiconductor device. The conventionally-known semiconductor device is designed to increase the volume of the cavity by forming a recess on the surface of the substrate.

In the aforementioned semiconductor device, a circuit chip for controlling the semiconductor chip is mounted on the surface of the substrate in parallel with the semiconductor chip.

Due to the parallel arrangement of the semiconductor chip and the circuit chip, which are attached onto the surface of the substrate, the overall size of the substrate becomes large; hence, it is difficult to downsize the semiconductor device.

Furthermore, the semiconductor device can be designed such that a conductive layer is formed on the surface of the substrate, and another conductive layer is formed in a cover member covering the semiconductor chip and the circuit chip mounted on the substrate, wherein these conductive layers are electrically connected together to form an electromagnetic shield to prevent electromagnetic disturbance on the semiconductor chip and the circuit chip.

In the above, the conductive layer of the substrate needs to be designed so as not to cause interference with electronic circuits and wirings of the semiconductor chip and circuit chip; and this is troublesome in circuit designing.

### SUMMARY OF THE INVENTION

It is an object of the present invention to provide a semiconductor device that can be downsized with ease.

It is another object of the present invention to provide a semiconductor device and a manufacturing method therefor, in which an electromagnetic shield embracing a semiconductor chip and a circuit chip can be formed with ease.

In a first aspect of the present invention, a semiconductor device includes a substrate, a semiconductor chip having a diaphragm, which vibrates in response to pressure variations, and a circuit chip that is electrically connected to the semiconductor chip so as to control the semiconductor chip, wherein the semiconductor chip is positioned opposite to and fixed to the surface of the circuit chip whose backside is attached onto the surface of the substrate.

In the above, a recess is formed and recessed from the surface of the circuit chip so that an opening thereof is positioned opposite to the diaphragm. In addition, a plurality of connection terminals are formed on the backside of the circuit chip so as to establish electrical connection with the substrate. Furthermore, a plurality of connection terminals are formed on the surface of the circuit chip and on the backside of the semiconductor chip, which is positioned opposite to the surface of the circuit chip, so as to establish electrical connection between the circuit chip and the semiconductor chip.

The aforementioned semiconductor device further includes a spacer having a rectangular shape, which is inserted between the semiconductor chip and the circuit chip, wherein the overall area of the spacer is smaller than the overall area of the surface of the circuit chip. In addition, a through hole is formed and runs through the spacer in its thickness direction so as to allow the diaphragm to be positioned opposite to the surface of the circuit chip via the through hole.

Due to the aforementioned structure adapted to the semiconductor device, it is possible to reduce the overall area of the surface of the substrate, on which the circuit chip and the semiconductor chip are mounted; hence, it is possible to downsize the semiconductor device with ease. The recess increases the volume of a cavity, which is formed in connection with the diaphragm, and it allows the diaphragm to vibrate freely. This makes it possible for the semiconductor device to accurately detect sound pressure variations by way of the vibration of the diaphragm. If a recess is formed in the substrate, the substrate must be increased in thickness in order to realize the required rigidity. That is, the aforementioned structure eliminates the necessity of forming an unwanted recess in the substrate; hence, it is possible to reduce the thickness of the substrate while securing the required rigidity.

Even though the connection terminals are formed on the surface of the circuit chip, which is positioned opposite to the backside of the semiconductor chip, it is possible to perform wire bonding so as to establish electrical connection between the connection terminals and the substrate; that is, it is possible to easily establish electrical connection between the circuit chip and the substrate.

The through hole of the spacer increases the volume of the cavity, allowing the diaphragm to vibrate; hence, it is possible to accurately detect sound pressure variations by way of the vibration of the diaphragm.

In a second aspect of the present invention, the aforementioned semiconductor device further includes a plurality of electrodes, which run through the circuit chip in its thickness direction from the surface thereof to the backside thereof; a plurality of connection terminals, which are formed on the backside of the semiconductor chip positioned opposite to the surface of the circuit chip and which are electrically connected to the plurality of electrodes; and a ring-shaped resin sheet, which is positioned in the surrounding area of the diaphragm and which is inserted between the semiconductor chip and the circuit chip, which thus join together without having a gap therebetween. The ring-shaped resin sheet is composed of a resin material that is softer than the semiconductor chip and the circuit chip.

The ring-shaped resin sheet is composed of an anisotropic conductive film, which has conductivity in the thickness direction thereof and an insulating ability along the surface thereof, and is positioned between the connection terminals and the electrodes, which are positioned opposite to each other. In addition, a recess is formed and recessed downwardly from the surface of the circuit chip so that an opening thereof is positioned opposite to the diaphragm.

Furthermore, a cover member, which includes a conductive member coated with an insulating film, is fixed to the surface of the semiconductor chip so as to cover the side portions of the semiconductor chip and the circuit chip, wherein an opening is formed at a prescribed position of the cover member so as to partially expose the diaphragm to the exterior.

In the above, it is possible to prevent the volume of the cavity from being unexpectedly changed during the manufacturing of the semiconductor device; it is possible to prevent the diaphragm from varying in vibration characteristic; and it is possible to improve the yield and manufacturing efficiency with respect to the semiconductor device. In addition, it is possible to reduce the stress which occurs between the semiconductor chip and the circuit chip joined together by way of the deformation of the ring-shaped resin sheet. Furthermore, the electrodes and the connection terminals are electrically connected together via the anisotropic conductive film with ease. The anisotropic conductive film contributes to a reduction of the pitch between the adjacent electrodes and a reduction of the pitch between the connection terminals; hence, it is possible to reduce the sizes of the semiconductor chip and circuit chip.

In a third aspect of the present invention, the aforementioned semiconductor device further includes a shield case for storing the semiconductor chip and the circuit chip therein, wherein the shield case, which is formed by coating a conductive member with an insulating film, includes a stage having a rectangular shape, which the circuit chip is fixed onto, a top portion, which is positioned opposite to the surface of the semiconductor chip and which has an opening allowing the diaphragm to be exposed to the exterior of the shield case, and a plurality of side walls, which are elongated from the side ends of the stage to the side ends of the top portion so as to surround the semiconductor chip and the circuit chip, which are vertically joined together, and wherein a plurality of through holes are formed in the stage so as to allow a plurality of connection terminals, which are formed on the backside of the circuit chip, to be exposed.

In the above, at least a first ground terminal and a second ground terminal, which are electrically connected to each other, are formed on the backside of the circuit chip, wherein the first ground terminal forms the connection terminal, and wherein the second ground terminal is positioned opposite to the surface of the stage, on which the conductive member is partially exposed and is electrically connected to the second ground terminal. Alternatively, a plurality of ground terminals are formed on the backside of the circuit chip and are inserted into a plurality of through holes, in which the conductive member is partially exposed in the interior surfaces thereof, so that the ground terminals are bought into contact with and are electrically connected to the conductive member.

In addition, the shield case is constituted of a cover member having the top portion and the side walls and a mount member having the stage, wherein the cover member is engaged with the mount member so as to form the shield case. A plurality of recesses are formed and recessed from the backside of the circuit chip so as to cover the surface of the stage except for the prescribed regions corresponding to the through holes.

Furthermore, a plurality of heat-dissipation holes are formed on the side walls so as to dissipate heat generated by the semiconductor chip and/or the circuit chip. The semiconductor chip and the circuit chip, which are vertically joined together, are adhered together by means of a ring-shaped resin sheet, which is positioned in the periphery of the diaphragm, without a gap therebetween. A recess is formed and recessed from the surface of the circuit chip, which is positioned opposite to the diaphragm.

A manufacturing method adapted to the semiconductor device includes three steps, i.e., a chip joining step, in which the semiconductor chip is attached onto the surface of the circuit chip in such a way that the diaphragm is positioned opposite to the circuit chip, so that the semiconductor chip and the circuit chip are fixed together and electrically connected together; a chip fixing step, in which the circuit chip is fixed onto the surface of the stage of the mount member so as to expose the connection terminals of the circuit chip to the exterior of the mount member via the through holes of the stage; and a case engaging step, in which the semiconductor chip and the circuit chip are covered with the cover member so that the cover member is engaged with the mount member so as to form the shield case, wherein the prescribed portions of the conductive member of the cover member are tightly engaged with the prescribed portions of the conductive member of the mount member so as to remove the insulating films therefrom, so that the conductive member of the cover member is brought into direct contact with the conductive member of the mount member.

In the chip fixing step, the ground terminals of the circuit chip are brought into contact with the conductive member of the stage. In the chip fixing step, the prescribed portions of the stage except for the prescribed regions corresponding to the through holes are engaged with the recesses of the circuit chip.

In the above, the shield case reliably prevents electromagnetic noise from being transmitted to the semiconductor chip and the circuit chip; hence, it is possible to reliably avoid the occurrence of operational errors of the semiconductor chip and the circuit chip due to electromagnetic noise. Herein, an electromagnetic shield can be easily formed by electrically connecting the ground terminals of the circuit chip to the conductive member of the stage.

Due to the formation of the recesses of the circuit chip, it is possible to establish precise positioning of the circuit chip relative to the stage with ease, and it is possible to reduce the thickness of the semiconductor device. When the connection terminals of the circuit chip are electrically connected to the substrate via solder balls, it is possible to reduce the pitch between the adjacent solder balls; hence, it is possible to downsize the circuit chip.

The heat-dissipation holes of the shield case allow heat, which is generated by the semiconductor chip and/or the circuit chip, to be dissipated to the exterior of the shield case with ease.

The ring-shaped resin sheet inserted between the semiconductor chip and the circuit chip prevents unexpected change of the volume of the cavity during the manufacturing of the semiconductor device; hence, it is possible to prevent the vibration characteristic of the diaphragm from being changed. That is, it is possible to improve the yield and manufacturing efficiency with respect to the semiconductor device.

The recess of the circuit chip increases the volume of the cavity with ease. This does not cause difficulty with respect to the vibration of the diaphragm; hence, it is possible to accurately detect sound pressure variations by way of the vibration of the diaphragm.

### BRIEF DESCRIPTION OF THE DRAWINGS

These and other objects, aspects, and embodiments of the present invention will be described in more detail with reference to the following drawings, in which:

FIG. 1 is a cross-sectional view showing a semiconductor device in accordance with a first embodiment of the present invention;

FIG. 2 is a cross-sectional view showing a semiconductor device in accordance with a first variation of the first embodiment;

FIG. 3 is a cross-sectional view showing a further modification of the first variation of the semiconductor device shown in FIG. 2;

FIG. 4 is a cross-sectional view showing a semiconductor device in accordance with a second variation of the first embodiment;

FIG. 5 is a cross-sectional view showing a further modification of the second variation of the semiconductor device shown in FIG. 4;

FIG. 6 is a cross-sectional view showing a semiconductor device in accordance with a third variation of the first embodiment;

FIG. 7 is a cross-sectional view showing a further modification of the third variation of the semiconductor device shown in FIG. 6;

FIG. 8 is a cross-sectional view showing a further modification of the third variation of the semiconductor device shown in FIG. 6;

FIG. 9 is a cross-sectional view showing a semiconductor device in accordance with a fourth variation of the first embodiment;

FIG. 10 is a cross-sectional view showing a semiconductor device in accordance with a second embodiment of the present invention;

FIG. 11A is a cross-sectional view showing a cover member used for manufacturing the semiconductor device of FIG. 10;

FIG. 11B is a cross-sectional view showing a silicon capacitor microphone chip used for manufacturing the semiconductor device of FIG. 10;

FIG. 11C is a cross-sectional view showing a ring-shaped resin sheet used for manufacturing the semiconductor device of FIG. 10;

FIG. 11D is a cross-sectional view showing an LSI chip used for manufacturing the semiconductor device of FIG. 10;

FIG. 12 is a cross-sectional view showing a variation of the semiconductor device in which the silicon capacitor microphone chip is reduced in size in comparison with the LSI chip;

FIG. 13 is a cross-sectional view showing another variation of the semiconductor device in which the silicon capacitor microphone chip is increased in size in comparison with the LSI chip;

FIG. 14 is a cross-sectional view showing a semiconductor device in accordance with a third embodiment of the present invention;

FIG. 15A is a cross-sectional view showing a cover member used for the manufacturing of the semiconductor device;

FIG. 15B is a cross-sectional view showing a silicon capacitor microphone chip used for the manufacturing of the semiconductor device;

FIG. 15C is a cross-sectional view showing a ring-shaped resin sheet used for the manufacturing of the semiconductor device;

FIG. 15D is a cross-sectional view showing an LSI chip used for the manufacturing of the semiconductor device;

FIG. 15E is a cross-sectional view showing a stage used for the manufacturing of the semiconductor device;

FIG. 16 is a plan view showing the backside of the LSI chip in connection with the stage and the cover member;

FIG. 17 is a cross-sectional view taken along line B-B in FIG. 16;

FIG. 18A is a perspective view showing the cover member;

FIG. 18B is a perspective view showing the silicon capacitor microphone chip and the LSI chip, which are vertically connected together and mounted on the stage;

FIG. 19 is a cross-sectional view showing a semiconductor device in accordance with a first variation of the third embodiment;

FIG. 20 is a plan view showing the backside of the LSI chip in connection with the stage and the cover member;

FIG. 21 is a cross-sectional view showing a semiconductor device in accordance with a second variation of the third embodiment;

FIG. 22 is a cross-sectional view showing a semiconductor device in accordance with a third variation of the third embodiment;

FIG. 23A is a perspective view showing a cover member incorporated in a semiconductor device in accordance with a fourth variation of the third embodiment; and

FIG. 23B is a perspective view showing a mount member, in which an LSI chip and a silicon capacitor microphone chip are mounted on a stage and which is covered with the cover member shown in FIG. 23A, thus completing the manufacturing of the semiconductor device in accordance with the fourth variation of the third embodiment.

### DESCRIPTION OF THE PREFERRED EMBODIMENTS

The present invention will be described in further detail by way of examples with reference to the accompanying drawings.

### 1. First Embodiment

FIG. 1 is a cross-sectional view showing the internal structure of a semiconductor device 1 in accordance with a first embodiment of the present invention. The semiconductor device 1 includes a circuit chip (hereinafter, referred to as an LSI chip) 5 and a semiconductor chip 7, which are sequentially formed on a surface 3a of a substrate 3. In addition, a cover member 9 is arranged so as to entirely cover the LSI chip 5 and the semiconductor chip 7 on the surface 3a of the substrate 3.

The substrate 3 is designed as a multilayered wiring substrate having electrical wirings (not shown), which establish electrical connection with the LSI chip 5 and the semiconductor chip 7.

The cover member 9 has a top portion 11 having a rectangular shape, which is positioned above the surface 3a of the substrate 3, and side walls 13, which are arranged in a ring shape and are fixed to the periphery of the surface 3a of the substrate 3. The cover member 9 as a whole has a recessed shape whose opening is directed downwardly toward the substrate 3.

Specifically, when the lower ends of the side walls 13 are attached onto the periphery of the surface 3a of the substrate 3, it is possible to form a hollow space S1 embracing the LSI chip 5 and the semiconductor chip 7 by means of the cover member 9 and the substrate 3. The hollow space S1 communicates with the external space (externally of the semiconductor device 1) via an opening 11a of the top portion 11.

The LSI chip 5 is used for controlling the semiconductor chip 7. Specifically, the LSI chip 5 includes an amplifier for amplifying electric signals output from the semiconductor chip 7, a digital signal processor (DSP) for digitally processing electric signals, and an A/D converter, for example. The LSI chip 5 is fixed to the surface 3a of the substrate 3 via an adhesive (not shown) such as silver paste.

The LSI chip 5 is electrically connected to the substrate 3 via wires 19, which are arranged between plural electrode pads 15 (formed on a surface 5a of the LSI chip 5) and plural electrode pads 17 (formed on the surface 3a of the substrate 3). Incidentally, the electrode pads 15 of the LSI chip 5 are positioned outside of a mounting area of the semiconductor chip 7 (which will be described later).

The semiconductor chip 7 is a sound pressure sensor chip (composed of silicon) for converting sound into electric signals. That is, the semiconductor chip 7 has a diaphragm 7a that vibrates in response to variations of sound pressure applied thereto from the external space existing externally of the semiconductor device 1. The diaphragm 7a is shaped and positioned so as to cause vibration in the thickness direction of the semiconductor chip 7. The semiconductor chip 7 has a recess 8 that is recessed downwardly from a backside 7b, which is positioned opposite to the surface 5a of the LSI chip 5. The diaphragm 7a is formed at the bottom of the recess 8. Incidentally, the recess 8 is formed by way of silicon etching, for example.

The semiconductor chip 7 is fixed to the surface 5a of the LSI chip 5 via an adhesive such as silver paste (not shown) in such a way that the diaphragm 7 is positioned opposite to the surface 5a of the LSI chip 5 via an air gap. In other words, a cavity S2 defined by the diaphragm 7 and the surface 5a of the LSI chip 5 is formed by means of the LSI chip 5 and the semiconductor chip 7.

The semiconductor chip 7 is electrically connected to the substrate 3 via wires 25, which are arranged between plural electrode pads 21 (formed on a surface 7a of the semiconductor chip 7) and plural electrode pads 23 (formed on the surface 3a of the substrate 3). In addition, the semiconductor chip 7 is electrically connected to the LSI chip 5 via the wires 19 and 25 as well as the electrode pads 17 and 23 of the substrate 3. All of the electrode pads 17 and 23 are positioned outside of the mounting area of the LSI chip 5 on the surface 3a of the substrate 3.

In the manufacturing of the semiconductor device 1 having the aforementioned structure, the ring-shaped side walls 13 are fixed to the periphery of the surface 3a of the substrate 3; then, the LSI chip 5 is fixed onto the surface 3a of the substrate 3 via the adhesive. Herein, the adhesive is applied to the periphery of the surface 3a of the substrate 3 in advance; then, the LSI chip 5 is adhered onto the periphery of the surface 3a of the substrate 3.

Next, the semiconductor chip 7 is fixed onto the surface 5a of the LSI chip 5 via the adhesive. Herein, the adhesive is applied to the prescribed area of the surface 5a of the LSI chip 5 in advance; then, the backside 7b of the semiconductor chip 7 is adhered to the prescribed area of the surface 5a of the LSI chip 5. That is, the gap between the surface 5a of the LSI chip 5 and the backside 7b of the semiconductor chip 7 is filled with the adhesive.

Thereafter, the LSI chip 5 and the semiconductor chip 7 are electrically connected to the substrate 3 via the wires 19 and 25 by way of wire bonding. Lastly, the top portion 11 is fixed to the ring-shaped side walls 13 so as to form the cover member 9, thus completing the manufacturing of the semiconductor device 1.

The aforementioned manufacturing process is an example of the manufacturing of the semiconductor device 1, which can be therefor modified as necessary. For example, the semiconductor chip 7 is firstly adhered to the LSI chip 5; then, the LSI chip 5 is fixed to the surface 3a of the substrate 3.

In the semiconductor device 1 in which the LSI chip 5 and the semiconductor chip 7 are vertically connected and fixed onto the surface 3a of the substrate 3, it is possible to reduce the overall area of the surface 3a of the substrate 3; hence, it is possible to downsize the semiconductor device 1 with ease.

The first embodiment can be further modified in a variety of ways, which will be described below.

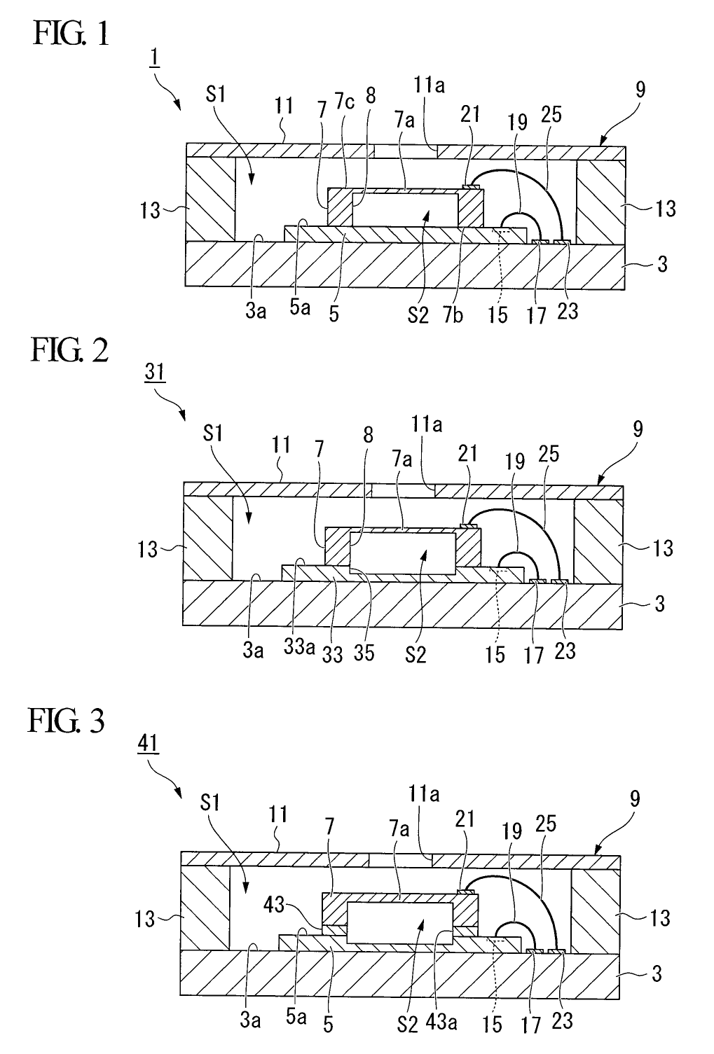

FIG. 2 is a cross-sectional view showing a semiconductor device 31 in accordance with a first variation of the first embodiment of the present invention. The semiconductor device 31 of the first variation has an LSI chip (or a circuit chip) 33, which structurally differs from the LSI chip 5 of the semiconductor device 1. Therefore, the following description is given mainly with respect to the structure of the LSI chip 33 in the semiconductor device 31, wherein parts identical to those of the semiconductor device 1 are designated by the same reference numerals; hence, the detailed description thereof is omitted as necessary.

The LSI chip 33 of the semiconductor device 31 is composed of silicon, and it functions similarly to the LSI chip 5 of the semiconductor device 1. Herein, the semiconductor chip 7 is fixed to a surface 33a of the LSI chip 33, which is partially recessed downwardly so as to form a recess 35 suiting the recess of the semiconductor chip 7. That is, the recess 35 of the LSI chip 33 is positioned opposite to the diaphragm 7a of the semiconductor chip 7. That is, the recess 35 increases the volume of the cavity S2 formed between the LSI chip 33 and the semiconductor chip 7. The recess 35 is formed by way of silicon etching, for example.

The semiconductor device 31 demonstrates effects similar to the effects of the semiconductor device 1. Due to the formation of the recess 35 of the LSI chip 33, it is possible to increase the volume of the cavity S2 with ease; hence, it is possible to reduce factors making it difficult for the diaphragm 7a to vibrate. This makes it possible to accurately detect sound pressure variations by way of the vibration of the diaphragm 7a.

In addition, the first variation eliminates the necessity of additionally forming a recess in the substrate 3 in order to enlarge the cavity S2. That is, the thickness of the substrate 3 is not necessarily increased in order to increase the rigidity; hence, it is possible to reduce the thickness of the substrate 3.

The semiconductor device 31 of the first variation is designed such that the recess 35 is formed in the LSI chip 33 so as to increase the volume of the cavity S2; but this is not a restriction. For example, it is possible to provide a semiconductor device 41 shown in FIG. 3 in which a spacer 43 having a rectangular shape is arranged between the LSI chip 5 (or LSI chip 33) and the semiconductor chip 7 so as to increase the volume of the cavity S2. Specifically, a through hole 43a running through vertically is formed in the spacer 43, by which the diaphragm 7a is positioned opposite to the surface 5a of the LSI chip 5.

The semiconductor device 41 can increase the volume of the cavity S2 by the thickness of the spacer 43 having the through hole 43a. Since the cavity S2 is increased in volume, the semiconductor device 41 reliably secures the vibration of the diaphragm 7a. Hence, it is possible to accurately detect sound pressure variations by way of the vibration of the diaphragm 7a.

Next, a semiconductor device 51 of a second variation of the first embodiment will be described with reference to FIG. 4. The semiconductor device 51 of the second variation structurally differs from the semiconductor device 1 with respect to the structure for arranging the semiconductor chip 7 on the substrate 3. Therefore, the following description is given with respect to the structural difference adapted to the semiconductor device 51, wherein parts identical to those of the semiconductor device 1 are designated by the same reference numerals; hence, the detailed description thereof will be omitted as necessary.

Specifically, the semiconductor device 51 is designed such that an LSI chip (or a circuit chip) 53, a spacer 55 having a rectangular shape, and the semiconductor chip 7 are sequentially mounted on the surface 3a of the substrate 3. Herein, the LSI chip 53 and the spacer 55 are adhered together via silver paste; the spacer 55 and the semiconductor chip 7 are adhered together via silver paste, for example. In this structure, the semiconductor chip 7 is attached onto a surface 55a of the spacer 55 in such a way that the diaphragm 7a is positioned opposite to the surface 55a of the spacer 55, whereby a cavity S3 is formed between the diaphragm 7a and the surface 55a of the spacer 55.

In the above, the overall area of a surface 53a of the LSI chip 53 is substantially identical to the overall area of the backside 7b of the semiconductor chip 7. That is, the shape of the LSI chip 53 in plan view substantially matches the shape of the semiconductor chip 7. In addition, the overall area of a backside 55b of the spacer 55, which is positioned opposite to the surface 53a of the LSI chip 53, is smaller than the overall area of the surface 53a of the LSI chip 53 and the overall area of the backside 7b of the semiconductor chip 7.

Due to the aforementioned structure, it is possible to form a gap whose dimensions substantially match the thickness of the spacer 55, between the LSI chip 53 and the semiconductor chip 7. A plurality of electrode pads (or connection terminals) 57 are formed in an exposed area of the surface 53a of the LSI chip 53, which is positioned opposite to the backside 7b of the semiconductor chip 7. The electrode pads 57 are electrically connected to the electrode pads 17 of the substrate 3 via wires 59.

In the manufacturing of the semiconductor device 51, which is similar to the manufacturing of the semiconductor device 1, the LSI chip 53 is fixed to the surface 3a of the substrate 3 via the adhesive. Then, the LSI chip 53 is electrically connected to the substrate 3 via the wires 59 by way of wire bonding.

Thereafter, the spacer 55 is fixed onto the surface 53a of the LSI chip 53 via the adhesive; then, the semiconductor device 7 is fixed onto the surface 55a of the spacer 55 via the adhesive. Herein, the gap between the backside of the semiconductor chip 7 and the surface 55a of the spacer 55 is filled with the adhesive.

Lastly, the semiconductor chip 7 is electrically connected to the substrate 3 via the wires 25 by way of wire bonding, thus completing the manufacturing of the semiconductor device 51. Incidentally, the cover member 9 is also attached to the substrate 3 in the semiconductor device 51 similar to the semiconductor device 1.

The semiconductor device 51 demonstrates effects similar to the effects of the semiconductor device 1. In the semiconductor device 51, even though the electrode pads 57 are arranged on the surface 53a of the LSI chip 53, which is positioned opposite to the backside 7b of the semiconductor chip 7, it is possible to perform wire bonding between the electrode pads 57 and the electrode pads 17 of the substrate 3 due to the insertion of the spacer 55; hence, it is possible to easily establish electrical connection between the LSI chip 53 and the substrate 3.

The second variation is characterized in that the overall area of the surface 53a of the LSI chip 53 is substantially identical to the overall surface of the backside 7b of the semiconductor chip 7. This contributes to a reduction of the mounting area for mounting the LSI chip 53 on the substrate 3; hence, it is possible to further downsize the substrate 3.

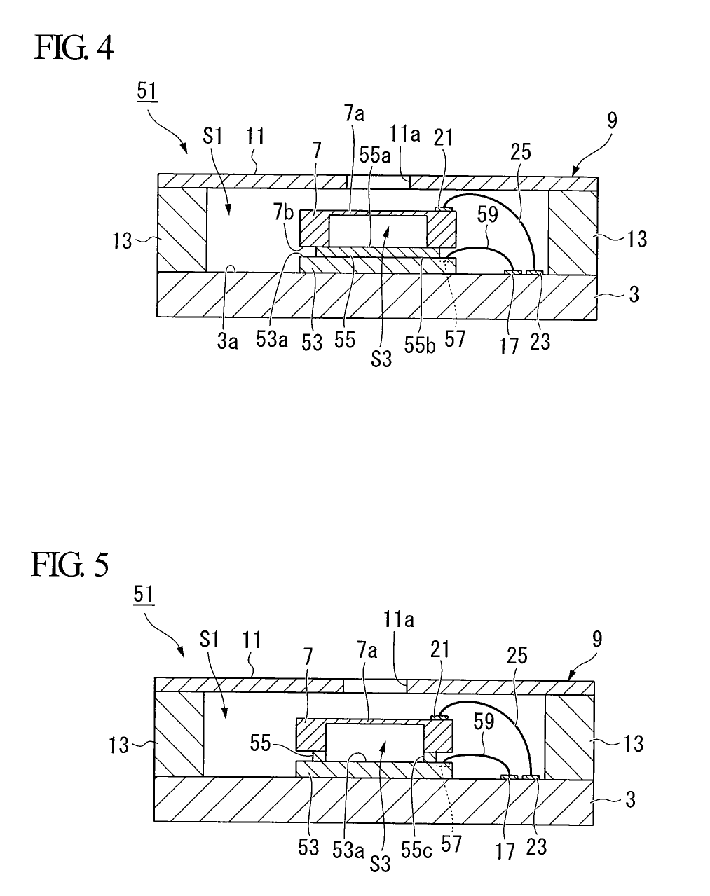

The semiconductor device 51 can be modified similar to the semiconductor device 41 shown in FIG. 3 in such a way that, as shown in FIG. 5, the spacer 55 has a through hole 55c allowing the diaphragm 3a to be positioned opposite to the LSI chip 54. This structure is advantageous in that wire bonding can be performed easily, and the volume of the cavity S3 can be increased.

In the semiconductor device 51, the overall area of the surface 53a of the LSI chip 53 is substantially identical to the overall area of the backside of the semiconductor chip 7; but this is not a restriction. That is, it is possible to modify the semiconductor device 51 in such a way that the overall area of the surface 53a of the LSI chip is smaller than the backside 7b of the semiconductor chip 7.

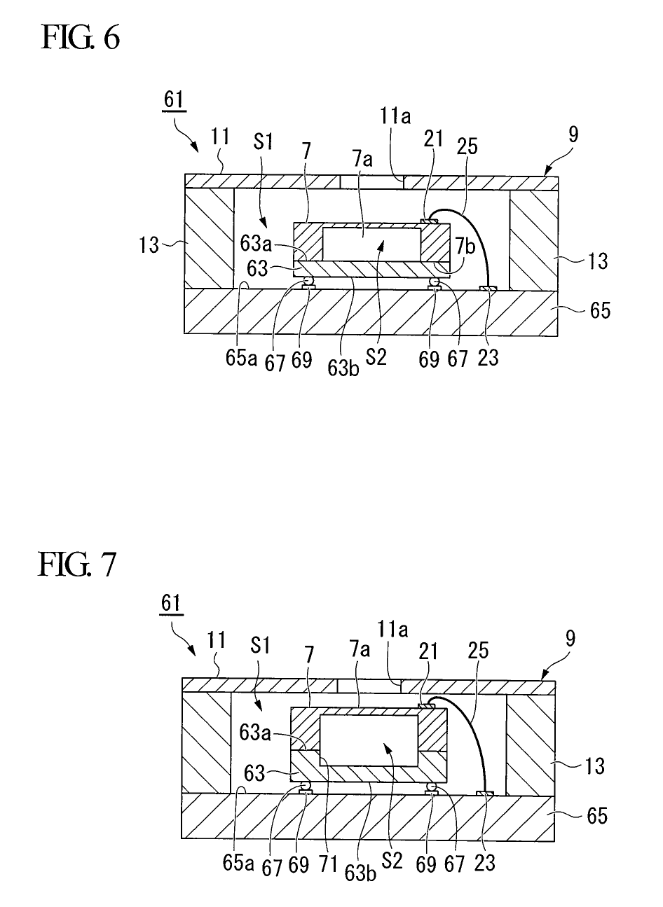

Next, a semiconductor device 61 of a third variation of the first embodiment will be described with reference to FIG. 6. The semiconductor device 61 structurally differs from the semiconductor device 1 with respect to the structure regarding an LSI chip (or a circuit chip) 61 and a substrate 65. The following description is given with respect to the structural difference in the semiconductor device 61, wherein parts identical to those of the semiconductor device 1 are designated by the same reference numerals; hence, the detailed description thereof will be omitted as necessary.

The semiconductor device 61 of the third variation is designed such that, similar to the semiconductor device 51 of the second variation, the overall area of a surface 65a of the substrate 65 is substantially identical to the overall area of backside 7b of the semiconductor chip 7. In addition, a plurality of solder balls 67 (serving as connection terminals) are formed on a backside 63b of the LSI chip 63, which is positioned opposite to the surface 65a of the substrate 65. The solder balls 67 project downwardly from the backside 63b of the LSI chip 63 so as to establish electrical connection between the LSI chip 63 and the substrate 65. That is, the semiconductor device 61 encapsulating the LSI chip 63 is designed to suit a surface mount package such as a chip size package.

A plurality of electrode pads 69 are formed on the surface 65a of the substrate 65 in the mounting area of the LSI chip 63, wherein they are brought into contact with the solder balls 67. That is, the LSI chip 63 is electrically connected to the substrate 65 via the solder balls 67 and is thus fixed onto the surface 65a of the substrate 65.

In the manufacturing of the semiconductor device 61, the LSI chip 63 is subjected to positioning relative to the substrate 65 in such a way that the backside 63b is positioned opposite to the surface 65a; then, the LSI chip 63 is pressed to the substrate 65 while heating the solder balls 67. Thus, the LSI chip 63 is fixed onto the surface 65a of the substrate 65 and is electrically connected to the substrate 65.

Thereafter, similar to the semiconductor device 1, the semiconductor chip 7 is fixed onto the surface 63a of the LSI chip 63 via the adhesive; then, the semiconductor chip 7 is electrically connected to the substrate 65 via the wires 25 by way of wire bonding, thus completing the manufacturing of the semiconductor device 61. Incidentally, the cover member 9 is also attached onto the substrate 65 in the semiconductor device 61 similar to the semiconductor device 1.

The semiconductor device 61 demonstrates effects similar to the effects of the semiconductor device 1. The semiconductor device 61 eliminates the necessity of arranging the foregoing electrode pads 17 on the peripheral area of the surface 65a of the substrate 65 outside of the mounting area of the LSI chip 63; hence, it is possible to reduce the overall area of the surface 65a of the substrate 65, which is simply required for mounting the LSI chip 63 thereon. This contributes to a further reduction of the overall area 65a of the substrate 65.

Similar to the semiconductor device 51, the semiconductor device 61 is designed such that the overall area of the surface 63a of the LSI chip 63 is substantially identical to the overall area of the backside 7b of the semiconductor chip 7; hence, it is possible to downsize the mounting area of the LSI chip 63 mounted on the substrate 65. By downsizing the substrate 65, it is possible to downsize the semiconductor device 61.

The semiconductor device 61 is characterized in that the LSI chip 63 is electrically connected to the substrate 65 via the solder balls 67 and is thus simultaneously fixed onto the surface 65a of the substrate 65; hence, it is possible to improve the manufacturing efficiency with regard to the semiconductor device 61.

The semiconductor device 61 can be modified similar to the semiconductor device 31 and 41 shown in FIGS. 2 and 3; in other words, it is possible to introduce a structure for increasing the volume of the cavity S2. For example, as shown in FIG. 7, a recess 71, which is recessed downwardly, can be formed in the LSI chip 63 by way of silicon etching.

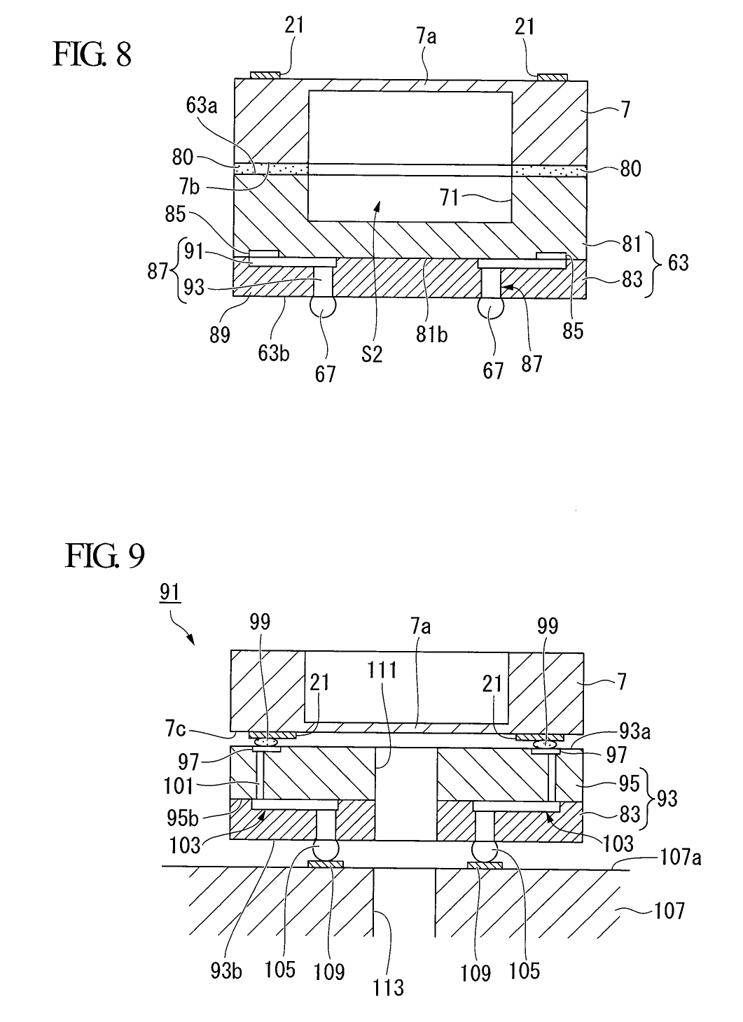

Alternatively, as shown in FIG. 8, the LSI chip 63 having the recess 71 is formed of two pieces, i.e., a main unit 81 having a rectangular shape (which forms the surface 63a) and a wiring package unit (which forms a backside 63b), which are combined together.

In the aforementioned structure, the recess 71 is formed in the main unit 81 composed of silicon in connection with the surface 63a, which is positioned opposite to the semiconductor chip 7. The main unit 81 is adhered to the semiconductor chip 7 via an adhesive 80 such as silver paste. In addition, a plurality of pad electrodes 85, which are electrically connected to the solder balls 67, are formed on a surface 81b of the main unit 81, which faces the wiring package unit 83.

The wiring package unit 83 includes wiring portions 87, which are used for establishing electrical connection between the pad electrodes 85 and the solder balls 67, and an insulating layer 89, which covers the surface 81b of the main unit 81 and which encloses the wiring portions 87 therein. Each of the wiring portions 87 is constituted by a re-wiring layer 91 and a copper post 93. The tip end of the copper post 93 is exposed externally of the backside 63b of the insulating layer 89 and is attached with the solder ball 67.

The first embodiment and the variations are all designed such that the electrode pads 21 of the semiconductor chips 7 are directly connected to the electrode pads 23 of the substrates 3 and 65 via the wires 25; but this is not a restriction. For example, the semiconductor chips 7 can be directly connected to the LSI chips 5, 33, 53, and 63; alternatively, the semiconductor chips 7 can be electrically connected to the substrates 3 and 65 via the LSI chips 5, 33, 53, and 63.

As shown in FIG. 9, a semiconductor device 91 is realized in accordance with a fourth variation of the first embodiment, in which the semiconductor chip 7 is fixed to a surface 93a of an LSI chip 93 in a direction reverse to the direction of the aforementioned semiconductor chips 7 fixed to the LSI chips 5, 33, 53, and 63 in the semiconductor chips 1, 31, 41, 51, and 61.

In the semiconductor device 91, a surface 7c of the semiconductor chip 7 having the pad electrodes 21 is positioned opposite to the surface 93a of the LSI chip 93, wherein the LSI chip 93 is constituted by a main unit 95 and the wiring package unit 83. A plurality of connection terminals 97 are formed on the surface 93a of the main unit 95 of the LSI chip 93 and are electrically connected to the pad electrodes 21 formed on the surface 7c of the semiconductor chip 7. Herein, the pad electrode 21 and the connection terminals 97 are electrically connected together and fixed together via solder 99.

A plurality of through holes 101 are formed and run through the main unit 95 (composed of silicon) in a direction from the surface 93a to the opposite surface 95b. The connection terminals 97 are electrically connected to wiring portions 103 via the through holes 101. Similar to the wiring portions 87 shown in FIG. 8, the wiring portions 9 include copper posts whose tip ends are attached with solder balls 105. That is, the pad electrodes 21 of the semiconductor chip 7 are electrically connected to electrode pads 109 formed on a surface 107a of a substrate 107 via the connection terminals 97, the through holes 101, the wiring portions 103, and the solder balls 105.

In the semiconductor device 91, the semiconductor chip 7 is electrically connected to the substrate 107 by simply attaching the semiconductor chip 7 onto the surface 93a of the LSI chip 93. This eliminates the necessity of additionally forming the electrode pads (which are used for establishing electrical connection with the semiconductor chip 7) on the peripheral area of the surface 107a of the substrate 107 outside of the mounting area of the LSI chip 93; hence, it is possible to reduce the prescribed area of the surface 107a of the substrate 107, which is used for mounting the semiconductor chip 7 and the LSI chip 93 thereon. Thus, it is possible to downsize the semiconductor device 91.

When solder balls are formed on a backside 93b of the LSI chip 93 so as to establish electrical connection with the substrate 107, it is unnecessary to form the electrode pads (which are used for establishing electrical connection between the semiconductor chip 7 and the LSI chip 93) on the peripheral area of the surface 107a of the substrate 107 outside of the mounting area of the LSI chip 93. This minimizes the prescribed area of the surface 107a of the substrate 107, which is used for mounting the semiconductor chip 7 and the LSI chip 93 thereon.

In order to realize the combination of the LSI chip 93 and the semiconductor chip 7, it is preferable that a through hole 111, which runs through the LSI chip 93 in its thickness direction, be formed and positioned relative to the diaphragm 7a, and it is also preferable that a communication hole 113, which runs through the substrate 107 in its thickness direction, be formed and opened upwardly toward the through hole 111.

Due to the aforementioned structure of the semiconductor device 91, sound pressure variations are transmitted to the diaphragm 7a via the communication hole 113 of the substrate 107 and the through hole 111 of the LSI chip 93. Herein, the recess of the semiconductor chip 7, which is positioned in contact with the diaphragm 7a but irrespective of the LSI chip 93, serves as the cavity allowing the diaphragm 7a to vibrate. Herein, the cavity is not limited in size by the substrate 107 and the LSI chip 93; hence, it is possible to easily enlarge the cavity.

The semiconductor devices 61 and 91 shown in FIGS. 6 to 9 are designed such that the solder balls 67 and 105 project downwardly from the backsides 63b and 93b of the LSI chip 63 and 93; but this is not a restriction. Because, it is required that the connection terminals be arranged on the backsides 63b and 93b so as to establish electrical connection between the LSI chips 63 and 93 and the substrates 65 and 107.

Incidentally, the semiconductor chip 7 is not necessarily designed as the sound pressure sensor chip having the diaphragm 7a. Because, it is required that the semiconductor chip 7 be equipped with a movable portion (such as the diaphragm 7a). That is, the semiconductor chip 7 can be designed as the pressure sensor chip, which detects pressure variations in the external space of the semiconductor device.

### 2. Second Embodiment

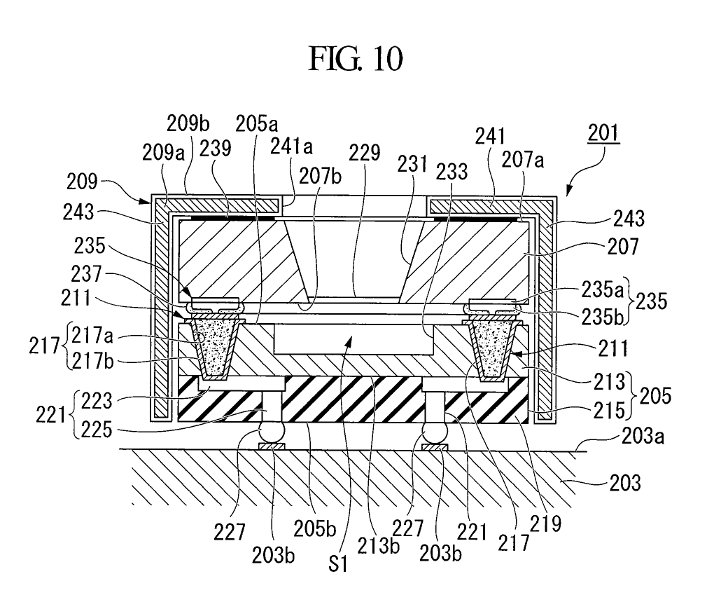

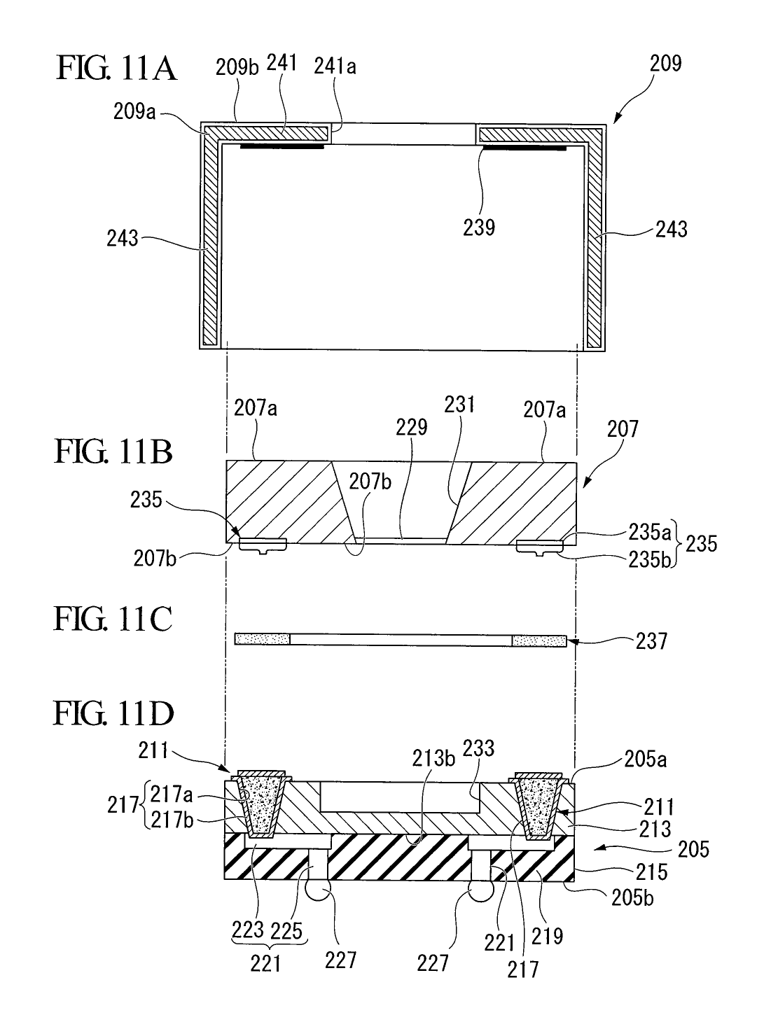

A second embodiment of the present invention will be described in detail with reference to FIG. 10, FIGS. 11A-11D, FIG. 12, and FIG. 13. A semiconductor device 201 of the second embodiment is mounted on a substrate (or a printed-circuit board) 203 and is constituted of an LSI chip (or a circuit chip) 205 mounted on a surface 203a of the substrate 203, a silicon capacitor microphone chip (or a semiconductor chip) 207 attached onto a surface 205a of the LSI chip 205, and a cover member 209 for covering the LSI chip 205 and the silicon capacitor microphone chip 207. Herein, both of the LSI chip 205 and the silicon capacitor microphone chip 207 are formed in substantially the same size. That is, when the LSI chip 205 and the silicon capacitor microphone chip 207 are vertically combined together, the silicon capacitor microphone chip 207 does not horizontally extend out of the LSI chip 205 in plan view.

A plurality of electrodes 211 are formed so as to run through the LSI chip 205 in its thickness direction from a backside 205b, which is positioned opposite to the surface 203a of the substrate 203, to a surface 205a, which is positioned opposite to the silicon capacitor microphone chip 207, so as to establish electrical connection between the silicon capacitor microphone chip 207 and the substrate 203. The LSI chip 205 is constituted of a main unit 213 (forming the surface 205a) and a wiring package unit 215 (forming the backside 205b).

The main unit 213 of the LSI chip 205 is composed of silicon and functions to control the silicon capacitor microphone chip 207. Specifically, the main unit 213 includes an amplifier for amplifying electric signals output from the silicon capacitor microphone chip 207, a digital signal processor (DSP) for digitally processing electric signals, and an A/D converter, for example.

A plurality of vias 217 are formed so as to run through the main unit 213 of the LSI chip 205 in its thickness direction from the surface 205a to a backside 213b. Each of the vias 217 is formed in such a way that a metal wire 217b composed of a conductive material is filled in a through hole 217a, which is formed so as to run through the main unit 213 in its thickness direction. That is, the upper end of the metal wire 217b is exposed to the surface 205a, and the lower end is exposed to the backside 213b. Incidentally, the metal wires 217b are formed at prescribed positions lying in the thickness direction of the main unit 213.

The wiring package unit 215 is constituted of an insulating layer 219, which covers the backside 213b of the main unit 213 of the LSI chip 205, and a plurality of wiring portions 221, which are sealed with the insulating layer 219 so as to electrically extend the metal wires 217b of the vias 217 toward the backside 205b of the LSI chip 205. That is, the aforementioned electrodes 211 are constituted of the vias 217 and the wiring portions 221.

The wiring portion 221 is constituted of a re-wiring layer 223, which is formed on the backside 213b of the main unit 213 of the LSI chip 205, and a copper post 225, which extends from the re-wiring layer 223 to the backside 205b of the LSI chip 205. The tip end of the copper post 225 is exposed externally of the backside 205b of the LSI chip 205 sealed with the insulating layer 219 and is attached with a solder ball 227. That is, the electrodes 211 of the LSI chip 205 join the electrode pads 203b, which are formed on the surface 203a of the substrate 203, via the solder balls 227.

Other wiring portions (not shown), which are connected to electronic circuits of the main unit 213 of the LSI chip 205 and which extend toward the backside 205b, are embedded inside of the wiring package unit 215. Similar to the wiring portions 221, the other wiring portions are constituted of re-wiring layers and copper posts.

The silicon capacitor microphone chip 207 is a sound pressure sensor chip composed of silicon, which converts sound into electric signals. The silicon capacitor microphone chip 207 has a diaphragm 229, which vibrates in response to sound pressure variations occurring in the external space existing externally of the semiconductor device 201. The diaphragm 229 is formed so as to vibrate in the thickness direction of the silicon capacitor microphone chip 207. A recess 231 is formed in the silicon capacitor microphone chip 207 by way of silicon etching, wherein it is recessed downwardly from a surface 207a of the silicon capacitor microphone chip 207, and wherein the bottom thereof corresponds to the diaphragm 229.

The silicon capacitor microphone chip 207 is mounted on the surface 205a of the LSI chip 205 in such a way that the diaphragm 229 is positioned opposite to the LSI chip 205. In addition, a recess 233 is formed in the LSI chip 205 and is recessed downwardly from the surface 205a.

A plurality of connection terminals 235, which project downwardly, are formed on the backside 207b of the silicon capacitor microphone chip 207, which is positioned opposite to the surface 205a of the LSI chip 205. Specifically, the connection terminals 235 are formed in such a way that stud bumps 235b project downwardly from electrode pads 235a, which are formed on the backside 207b. The stud bumps 235b composed of gold (Au) are formed by way of wire bonding, wherein each of them has a projected structure whose height ranges from 30 μm to 40 μm, for example.

The connection terminals 235 are positioned opposite to the upper ends of the metal wires 217b, which are embedded in the vias 217 and which are exposed onto the surface 205a of the LSI chip 205, wherein they are electrically connected to the electrodes 211 of the LSI chip 205. In other words, the connection terminals 235 are positioned opposite to the metal wires 217b embedded in the through holes 217a.

Therefore, the silicon capacitor microphone chip 207 electrically joins the substrate 203 via the electrodes 211. When the connection terminals 235 are mounted on the metal wires 217b of the vias 217, a gap is formed between the surface 205a of the LSI chip 205 and the backside 207b of the silicon capacitor microphone chip 207 by way of the stud bumps 235b.

A ring-shaped resin sheet 237 is inserted between the electrodes 211 of the LSI chip 205 and the connection terminals 235 of the silicon capacitor microphone chip 207 and is positioned in the surrounding area of the diaphragm 229. The ring-shaped resin sheet 237 realizes the adhesion between the LSI chip 205 and the silicon capacitor microphone chip 207. Specifically, the ring-shaped resin sheet 237 is formed using an anisotropic conductive film (AFC) having conductivity in the thickness direction and insulating ability along the surface.

Specifically, the anisotropic conductive film is formed by introducing conductive particles into a conductive resin material which is softer than the materials of the LSI chip 205 and the silicon capacitor microphone chip 207. Herein, the conductive resin material is composed of an epoxy resin or a polyimide resin; and the conductive particles are composed of plastic particles or Ni particles subjected to gold plating or silver plating, for example.

The LSI chip 205 and the silicon capacitor microphone chip 207 are joined together by way of the adhesion realized by the conductive resin material of the ring-shaped resin sheet 237 without a gap therebetween. The electrodes 211 and the connection terminals 235 are electrically connected together via the conductive particles included in the ring-shaped resin sheet 237.

When the LSI chip 205 and the silicon capacitor microphone chip 207 are vertically joined together, a hollow cavity S1 is formed between the diaphragm 229 and the LSI chip 205. Specifically, the cavity S1 is formed by a gap between the prescribed area of the surface 205a of the LSI chip 205 and the prescribed area of the backside 207b of the silicon capacitor microphone chip 207, both of which are surrounded by the ring-shaped resin sheet 237, and the recess 233, which is recessed downwardly from the surface 205a of the LSI chip 205. Since the LSI chip 205 and the silicon capacitor microphone chip 207 are adhered together without a gap therebetween by way of the ring-shaped resin sheet 237, the cavity S1 is closed in an airtight manner and does not communicate with the external space of the semiconductor device 201.

The cover member 209 is formed so as to cover the surface 207a of the silicon capacitor microphone chip 207 and the side areas of the LSI chip 205 and the silicon capacitor microphone chip 207. Specifically, the cover member 209 is constituted of a top portion 241, which is fixed to the surface 207a of the silicon capacitor microphone chip 207 via an adhesive 239, and a cylindrical portion 243, which extends downwardly form the periphery of the top portion 241 in the direction, in which the LSI chip 205 and the silicon capacitor microphone chip 207 are vertically joined together, so as to surround the side areas of the LSI chip 205 and the silicon capacitor microphone chip 207. In addition, an opening 241a is formed approximately at the center of the top portion 241 so that the silicon capacitor microphone chip 207 is partially exposed to the external space.

The internal capacity of the cover member 209 substantially matches the total volume in which the LSI chip 205 and the silicon capacitor microphone chip 207 are vertically joined together. That is, the top portion 241 of the cover member 209 is positioned opposite to the surface 207a of the silicon capacitor microphone chip 207 via an adhesive 239; and the cylindrical portion 243 is positioned opposite to the side areas of the LSI chip 205 and the silicon capacitor microphone chip 207 with small gaps therebetween.

The cover member 209 is formed in such a way that a conductive member 209a, which is shaped to realize the top portion 241 and the cylindrical portion 243, is coated with an insulating film 209b. Specifically, the conductive member 209a composed of aluminum is subjected to alumite treatment, thus forming the insulating film 209b.

In the manufacturing of the semiconductor device 201, the ring-shaped resin sheet 237 is positioned at the peripheral area of the recess 233 and is temporarily fixed onto the surface 205a of the LSI chip 205, wherein the ring-shaped resin sheet 237 is arranged on the metal wires 217b of the vias 217 as well. Simultaneously with the temporary fixing of the ring-shaped resin sheet 237, or before or after the temporary fixing of the ring-shaped resin sheet 237, the connection terminals 235 are formed in such a way that the stud bumps 235b are formed on the electrode pads 235a, which are formed on the backside 207b of the silicon capacitor microphone chip 207. Next, the silicon capacitor microphone chip 207 is attached onto the surface 205a of the LSI chip 205 in such a way that the connection terminals 235 are positioned opposite to the metal wires 217b of the vias 217.

In the above, pressure is applied downwardly via the silicon capacitor microphone chip 207 so as to heat the ring-shaped resin sheet 237, whereby the conductive resin material of the ring-shaped resin sheet 237 is melted so that the stud bumps 235b move downwardly into the ring-shaped resin sheet 237; hence, the conductive particles included in the ring-shaped resin sheet 237 are sandwiched between the metal wires 217b and the stud bumps 235b. Thus, the LSI chip 205 and the silicon capacitor microphone chip 207 are mutually adhered and fixed together, so that the electrodes 211 are electrically connected to the connection terminals 235.

Lastly, the cover member 209 is precisely positioned so as to cover the LSI chip 205 and the silicon capacitor microphone chip 207; then, the top portion 241 of the cover member 209 is fixed onto the surface 207a of the silicon capacitor microphone chip 207 via the adhesive 239, thus completing the manufacturing of the semiconductor device 201.

In order to mount the semiconductor device 201 on the substrate (or printed-circuit board) 203, the backside 205b of the LSI chip 205 is positioned opposite to the surface 203a of the substrate 203 so as to bring the solder balls 227 into contact with the electrode pads 203b; then, the semiconductor device 201 is pressed to the substrate 203 while the solder balls 227 are heated. Thus, the semiconductor device 201 is fixed onto the surface 203a of the substrate 203, so that both of the LSI chip 205 and the silicon capacitor microphone chip 207 are electrically connected to the substrate 203.

In the semiconductor device 201, when sound pressure variations are transmitted to the diaphragm 229 of the silicon capacitor microphone chip 207 via the opening 241a of the cover member 209, the diaphragm 229 vibrates in response to sound pressure variations transmitted thereto, thus making it possible to detect sound pressure variations.

The present embodiment is advantageous in that, by simply mounting the semiconductor device 201, in which the silicon capacitor microphone chip 207 and the LSI chip 205 are vertically joined together, on the surface 203a of the substrate 203, the silicon capacitor microphone chip 207 is electrically connected to the substrate 203 via the electrodes 211. That is, the present embodiment is advantageous in comparison with the conventional technology because it eliminates the necessity of individually mounting the silicon capacitor microphone chip 207 and the LSI chip 205 on the substrate 203. This makes it possible to downsize the semiconductor device 201 with ease; hence, it is possible to reduce the mounting area of the semiconductor device 201 mounted on the surface 203a of the substrate 203. In other words, the semiconductor device 201 can be realized by way of a chip size package.

The volume of the cavity S1, which is formed between the diaphragm 229 and the LSI chip 205, can be easily determined in response to the size and shape of the ring-shaped resin sheet 237, which is formed in advance. Hence, it is possible to prevent the volume of the cavity S1 from being unexpectedly changed during the manufacturing of the semiconductor device 201; and it is therefore possible to prevent the vibration characteristic of the diaphragm 229 from being unexpectedly changed during the manufacturing of the semiconductor device 201. Therefore, it is possible to improve the yield and manufacturing efficiency with respect to the semiconductor device 201.

The volume of the cavity S1 can be easily increased by way of the recess 233, which is formed in the LSI chip 205. This makes it easy for the diaphragm 229 to vibrate without difficulty. Thus, it is possible to accurately detect sound pressure variations by way of the vibration of the diaphragm 229.

The second embodiment eliminates the necessity of additionally forming a recess in the substrate 203 in order to enlarge the cavity S1; hence, it is unnecessary to increase the thickness of the substrate 203 in order to realize the required rigidity. Thus, it is possible to easily reduce the thickness of the substrate 203 for mounting the semiconductor device 201.

The anisotropic conductive film is used for the ring-shaped resin sheet 237, which is used for adhering the silicon capacitor microphone chip 207 and the LSI chip 205 together, whereby the metal wires 217b of the vias 217 are brought into contact with and electrically connected to the connection terminals 235 via the ring-shaped resin sheet 237. That is, the vias 217 and the connection terminals 235 are joined together by way of the anisotropic conductive film. This eliminates the necessity of additionally preparing adhesive material realizing the adhesion between the vias 217 and the connection terminals 235; hence, this makes it easy for the vias 217 to electrically join the connection terminals 235.

The anisotropic conductive film prevents the vias 217, which are positioned adjacent to each other on the surface 205a of the LSI chip 205, from being electrically joined together. Similarly, the anisotropic conductive film prevents the connection terminals 235, which are positioned adjacent to each other on the backside 207b of the silicon capacitor microphone chip 207, from being electrically joined together. Hence, it is possible to reduce the pitch between the adjacent vias 217b with ease; and it is possible to reduce the pitch between the adjacent connection terminals 235 with ease. Thus, it is possible to further downsize the LSI chip 205 and the silicon capacitor microphone chip 207.

The resin material of the anisotropic conductive film, which realizes the adhesion between the LSI chip 205 and the silicon capacitor microphone chip 207, is softer than the materials of the LSI chip 205 and the silicon capacitor microphone chip 207. That is, it is possible to reduce the stress, which occurs between the LSI chip 205 and the silicon capacitor microphone chip 207 adhered together, by way of the deformation of the ring-shaped resin sheet 237.

Due to the provision of the cover member 209 that entirely covers the LSI chip 205, the silicon capacitor microphone chip 207, and the adhered areas therebetween, it is possible to reliably secure the protection with regard to the semiconductor device 201. Hence, it is possible to reliably mount the semiconductor device 201 on the surface 203a of the substrate 203 while securing the protection therefor because the LSI chip 205 and the silicon capacitor microphone chip 207 vertically joined together are covered with the cover member 109, which is fixed to the silicon capacitor microphone chip 207.

The internal capacity of the cover member 209 can be determined to suit the sizes of the LSI chip 205 and the silicon capacitor microphone chip 207; hence, it is possible to secure the protection of the semiconductor device 201 without increasing the size of the semiconductor device 201.

When the conductive member 209a of the cover member 209 electrically joins a ground pattern (not shown) of the substrate 203, it is possible to form an electromagnetic shield for preventing electromagnetic noise from being transmitted inside of the cover member 209 from the external space. This makes it possible to reliably prevent electromagnetic noise from reaching the LSI chip 205 and the silicon capacitor microphone chip 207. In other words, it is possible to reliably avoid the occurrence of operational errors of the LSI chip 205 and the silicon capacitor microphone chip 207 due to electromagnetic noise.

The insulating film 209b, which is formed on the surface of the conductive member 209a, prevents electronic circuits, which are included in the LSI chip 205 and the silicon capacitor microphone chip 207, from being short-circuited by way of the cover member 209.

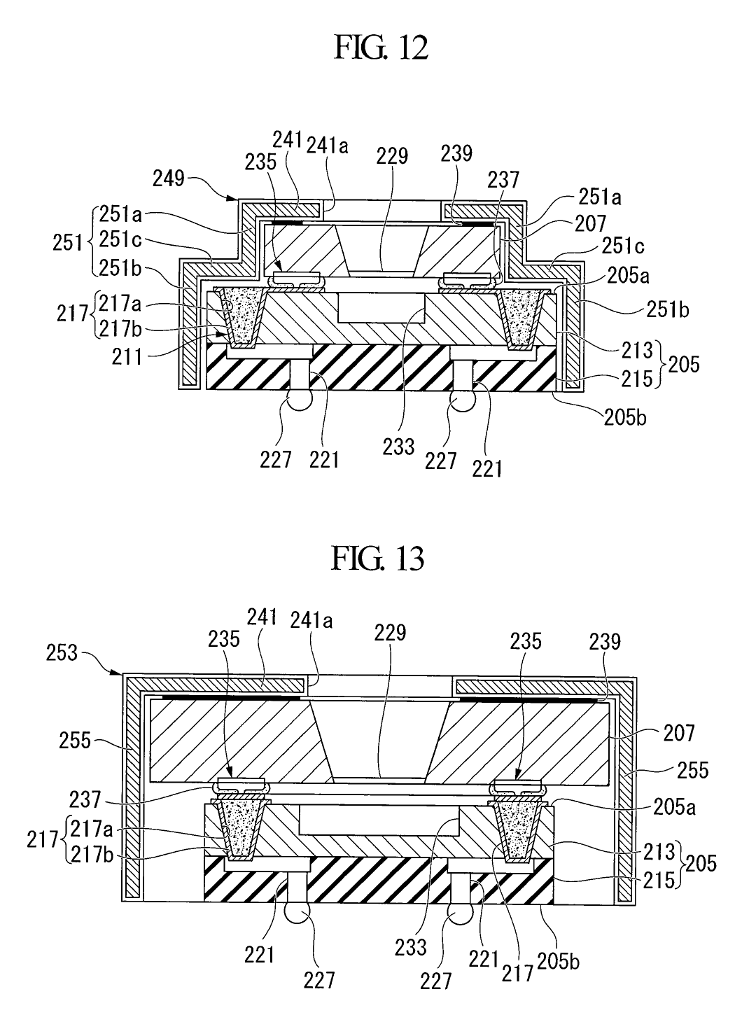

In the present embodiment, the semiconductor device 201 includes the LSI chip 205 and the silicon capacitor microphone chip 207, both of which have the same size; but this is not a restriction. That is, the present embodiment can be adapted to another type of semiconductor device including the LSI chip and silicon capacitor microphone chip having different sizes. For example, the semiconductor device 201 can be modified as shown in FIG. 12, wherein parts identical to those shown in FIG. 10 are designated by the same reference numerals; hence, the detailed description thereof will be omitted as necessary. Herein, the silicon capacitor microphone chip 207 is reduced in size in comparison with the LSI chip 205. That is, the side portions of the LSI chip 205 partially extend from the side portions of the silicon capacitor microphone chip 207 in plan view.

A newly-designed cover member 249 for covering the LSI chip 205 and the silicon capacitor microphone chip 207 vertically joined together is introduced to cope with the aforementioned structure. The cover member 249 is formed using a cylindrical portion 251, which has a step portion 251c. This makes it possible for the cylindrical portion 251 to be positioned opposite to the side portions of the LSI chip 205 and the silicon capacitor microphone chip 207 with small gaps therebetween.

Specifically, the cylindrical portion 251 is constituted of a small-diameter portion having a cylindrical shape, which is positioned to embrace the silicon capacitor microphone chip 207 therein with a small gap therebetween, a large-diameter portion 251b having a cylindrical shape, which is formed below the small-diameter portion 251a and is positioned to embrace the LSI chip 205 therein with a small gap therebetween, as well as the step portion 251c having a ring shape for interconnecting the small-diameter portion 251a and the large-diameter portion 251b together.

In the aforementioned structure in which the silicon capacitor microphone chip 207 is reduced in size in comparison with the LSI chip 205, the connection terminals 235 are slightly shifted in position away from the through holes 217a, wherein the metal wires 217b are horizontally extended along the surface 205a of the LSI chip 205 toward the prescribed positions just below the connection terminals 235. In this case, the metal wires 217b are not necessarily extended downwardly in the through holes 217a in the thickness direction of the LSI chip 205.

Alternatively, it is possible to increase the silicon capacitor microphone chip 207 in size in comparison with the LSI chip 205. This structure will be described with reference to FIG. 13, wherein parts identical to those shown in FIG. 10 are designated by the same reference numerals; hence, the detailed description thereof will be omitted as necessary. That is, the side portions of the silicon capacitor microphone chip 207 partially extend from the side portions of the LSI chip 205 in plan view. This structure uses a cover member 253 constituted by the top portion 241 and a cylindrical portion 255 having a relatively large capacity, wherein the cylindrical portion 255 is positioned opposite to the side portions of the silicon capacitor microphone chip 207 with a small gap therebetween. In this structure, the cylindrical portion 255 is positioned opposite to the side portions of the LSI chip 205 with a relatively large gap therebetween.

In this structure, it is necessary to precisely determine the positions of the connection terminals 235 formed on the backside 207b of the silicon capacitor microphone chip 207 in such a way that the connection terminals 235 are positioned opposite to the upper ends of the metal wires 217b exposed on the surface 205a of the LSI chip 205.

The second embodiment and its variations can be further modified in a variety of ways, which will be described below.
(1) The cover members 209, 249, and 253 are each designed such that the insulating film 209bis formed on the surface of the conductive member 209a; but this is not a restriction. It is required to form an electromagnetic shield for shielding electromagnetic noise from being transmitted into the cover members 209, 249, and 253 from the external space. That is, the cover member 209 can be formed using a conductive film composed of carbon micro-coil, for example.
(2) The solder balls 227 project from the backside 205b of the LSI chip 205; but this is not a restriction. It is required that connection terminals for establishing electrical connection between the LSI chip 205 and the substrate 203 be formed on the backside 205b. That is, the copper posts 225 can be projected from the backside 205b of the LSI chip 205, for example.
(3) The LSI chip 205 is not necessarily formed by the main unit 213 and the wiring packaging unit 215. That is, the LSI chip 205 can be formed using the main unit 213 only. In this case, the electrodes 211 are formed using the vias 217 only.
(4) The ring-shaped resin sheet 237 is not necessarily composed of the anisotropic conductive film. It is required that the ring-shaped resin sheet 237 be composed of a resin material that is softer than the materials of the LSI chip 205 and the silicon capacitor microphone chip 207. In this case, it is preferable that the electrodes 211 join the connection terminals 235 via another joining material such as solder and conductive adhesive. Herein, the conductive adhesive is mainly composed of a resin material such as epoxy resin.
(5) When the electrodes 211 join the connection terminals 235 via the solder, the solder is printed on the vias 217, whose upper ends are exposed on the surface 205a of the LSI chip 205, in advance; then, the ring-shaped resin sheet 237 is temporarily fixed onto the surface 205a of the LSI chip 205. Next, the silicon capacitor microphone chip 207 is attached onto the surface 205a of the LSI chip 205; then, pressure is applied in the direction from the silicon capacitor microphone chip 207 so as to heat the ring-shaped resin sheet 237 and the solder.
(6) When the electrodes 211 join the connection terminals 235 via the conductive adhesive, the conductive adhesive is applied to the stud bumps 235b of the silicon capacitor microphone chip 207 in advance; then, the ring-shaped resin sheet 237 is temporarily fixed onto the surface 205a of the LSI chip 205. Next, the silicon capacitor microphone chip 207 is attached onto the surface 205a of the LSI chip 205; then, pressure is applied in the direction from the silicon capacitor microphone chip 207 so as to heat the ring-shaped resin sheet 237 and the conductive adhesive. In this case, the stud bumps 235b move downwardly into the ring-shaped resin sheet 237 so as to come in contact with the conductive adhesive. Due to the heating, the resin material included in the conductive adhesive is melted as well, so that the stud bumps 235b join the vias 217 via the conductive adhesive.
(7) The recess 233 is formed and recessed downwardly from the surface 205a of the LSI chip 205 so that the opening thereof is positioned opposite to the diaphragm 229; but this is not a restriction. That is, the recess 233 is not necessarily formed as long as the gap, which forms the cavity S1 and which is formed between the surface 205a of the LSI chip 205 and the backside 207b of the silicon capacitor microphone chip 207, has a relatively large volume guaranteeing the accurate detection of sound pressure variations by way of the vibration of the diaphragm 229.
(8) The silicon capacitor microphone chip 207 is not necessarily designed as the sound pressure sensor chip having the diaphragm 229. It is required that the diaphragm 229 of the silicon capacitor microphone chip 207 have a moving part. Therefore, the silicon capacitor microphone chip 207 can be designed as the pressure sensor that detects pressure variations occurring in the external space of the semiconductor device 201, for example.

### 3. Third Embodiment

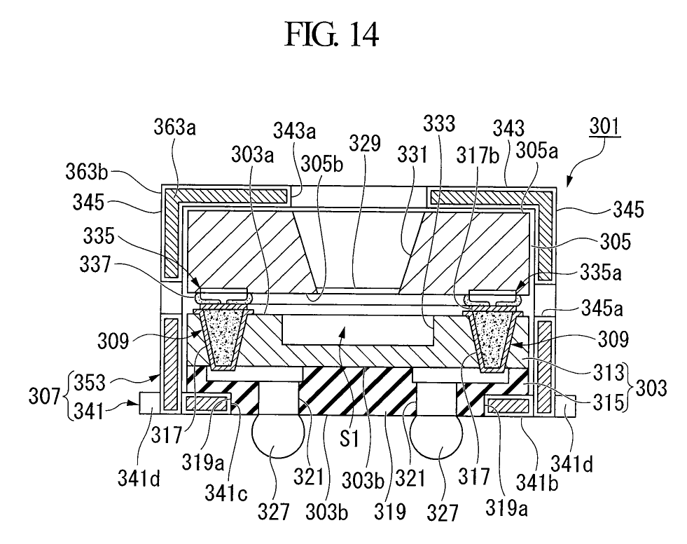

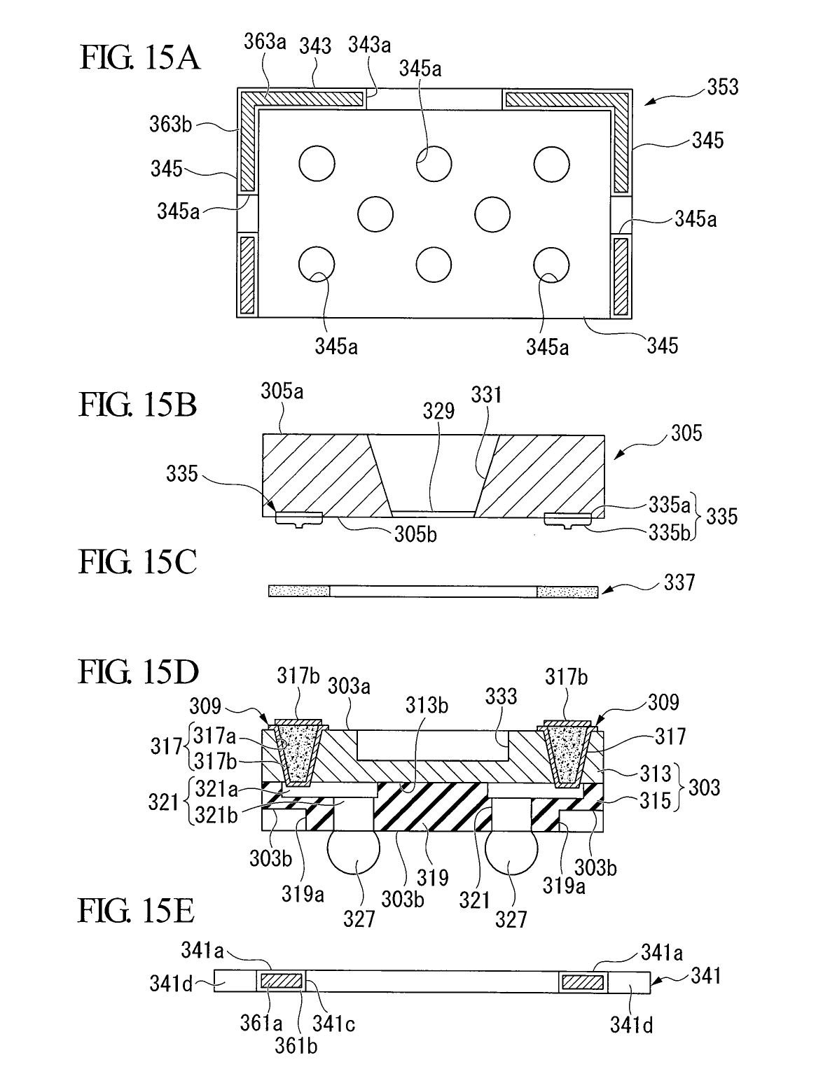

With reference to FIG. 14, FIGS. 15A-15E, and FIGS. 16-17, and FIGS. 18A and 18B, a semiconductor device 301 will be described in accordance with a third embodiment of the present invention. The semiconductor device 301, which is mounted on a substrate (or a printed-circuit board, not shown), is designed to include an LSI chip (or a circuit chip) 303, a silicon capacitor microphone chip (or a semiconductor chip) 305, which is attached onto a surface 303a of the LSI chip 303 and is electrically connected together with the LSI chip 303, and a shield case 307 for embracing the LSI chip 303 and the silicon capacitor microphone chip 305 therein. Both of the LSI chip 303 and the silicon capacitor microphone chip 305 are the same size in plan view. That is, when the silicon capacitor microphone chip 305 is vertically combined with the LSI chip 303, the side portions of the silicon capacitor microphone chip 305 do not extend from the side portions of the LSI chip 303 in plan view.

The LSI chip 303 is mounted on a stage 341 of the shield case 307 (see FIG. 15E), which will be described later. A plurality of connection terminals 309 (see FIG. 15D) are formed on a backside 303b of the LSI chip 303, which is positioned opposite to the stage 341, so as to establish electrical connection with the substrate (not shown). Each of the connection terminals 309 runs through in the thickness direction of the LSI chip 303 from the backside 303b to the surface 303a facing the silicon capacitor microphone chip 305; in other words, the connection terminals 309 form electrodes for establishing electrical connection between the silicon capacitor microphone chip 305 and the substrate.

The LSI chip 303 is constituted of a main unit 313 (forming the surface 303a) and a wiring package unit 315 (forming the backside 303b). The main unit 313 is composed of silicon and is designed to control the silicon capacitor microphone chip 305. That is, the main unit 313 of the LSI chip 303 includes an amplifier for amplifying electric signals output from the silicon capacitor microphone chip 305, a digital signal processor (DSP) for digitally processing electric signals, and an A/D converter, for example.

A plurality of vias 317 are formed in the main unit 313 of the LSI chip 303 in such a way that they run through the main unit 313 in the thickness direction, so that the upper ends thereof are exposed on the surface 303a, and the lower ends thereof are exposed on a backside 313b of the main unit 313. The vias 317 are formed in such a way that metal wires 317b composed of conductive materials are embedded in through holes 317a, which run through the main unit 313 in the thickness direction. Hence, the upper ends of the metal wires 317b are exposed on the surface 303a, and the lower ends thereof are exposed on the backside 313b. The metal wires 317b extend in the thickness direction of the main unit 313.

The wiring package unit 315 includes a plurality of wiring portions 321, which are sealed with an insulating layer 319 so as to establish electrical wiring regarding the metal wires 317b (embedded in the vias 317) toward the backside 303b of the LSI chip 303, wherein the backside 313b of the main unit 313 is covered with the insulating layer 319. That is, the vias 317 and the wiring portions 321 form the aforementioned electrodes corresponding to the connection terminals 309.

Each of the wiring portions 321 is constituted by a re-wiring layer 321a, which is formed on the backside 313b of the main unit 313, and a copper post 321b, which extends from the re-wiring layer 321a to the backside 303b of the LSI chip 303. The tip ends of the copper posts 321b are exposed externally of the backside 303b of the LSI chip 303 (sealed with the insulating layer 319) and are attached with solder balls 327. The connection terminals 309 of the LSI chip 303 electrically join electrode pads (not shown), which are formed on the surface of the substrate, via the solder balls 327.

Other wiring portions (not shown) are embedded in the wiring package unit 315 so as to establish electrical wiring for electronic circuits of the main unit 313 toward the backside 303b of the LSI chip 303, wherein they serve as connection terminals for establishing electrical connection between the LSI chip 303 and the substrate. Similar to the wiring portions 321, the wiring portions embedded in the wiring package unit 315 are composed of re-wiring layers and copper posts.

The silicon capacitor microphone chip 305 is a sound pressure sensor composed of silicon, which converts sound into electric signals. The silicon capacitor microphone chip 305 has a diaphragm 329, which vibrates in response to sound pressure variations occurring in the external space existing externally of the semiconductor device 301. The diaphragm 329 vibrates in the thickness direction of the silicon capacitor microphone chip 305. A recess 331 is formed in the silicon capacitor microphone chip 305 by way of silicon etching and is recessed downwardly from the surface 305a, so that the bottom of the recess 331 corresponds to the diaphragm 329.

The silicon capacitor microphone chip 305 is attached onto the surface 303a of the LSI chip 303 in such a way that the diaphragm 329 is positioned opposite to the LSI chip 303. In addition, a recess 333 is formed in the LSI chip 303 and is recessed downwardly from the surface 303a, which the diaphragm 329 is positioned opposite to.

A plurality of connection terminals 335 are formed on the backside 305b of the silicon capacitor microphone chip 305, which is positioned opposite to the surface 303a of the LSI chip 303. Specifically, the connection terminals 335 are formed in such a way that stud bumps 335b project downwardly from electrode pads 335a formed on the backside 305b. Herein, the stud bumps 335b are composed of gold (Au) and are formed by way of wire bonding, thus realizing projected structures whose heights range from 20 μm to 50 μm, for example. Alternatively, the stud bumps 335b are formed by way of electrical plating, thus realizing projected structures whose heights range from 20 μm to 80 μm, for example. They are composed of gold (Au) or solder (i.e., an alloy including tin (Sn) and silver (Ag), for example.

The connection terminals 335 are positioned opposite to the metal wires 317b of the vias 317, which are exposed on the surface 303a of the LSI chip 303, and are electrically connected to the connection terminals 309. Herein, the connection terminals 335 are positioned opposite to the upper ends of the metal wires 317b embedded in the through holes 317a.

Thus, the silicon capacitor microphone chip 305 is electrically connected to the substrate via the connection terminals 309 serving as the electrodes. When the connection terminals 335 are mounted on the metal wires 317b of the vias 317, a gap is formed between the surface 303a of the LSI chip 303 and the backside 305b of the silicon capacitor microphone chip 305 by way of the stud bumps 335b.

A ring-shaped resin sheet 337, which is arranged in the periphery of the diaphragm 329, is inserted between the connection terminals 309 of the LSI chip 303 and the connection terminals 335 of the silicon capacitor microphone chip 305. The ring-shaped resin sheet 337 realizes adhesion between the LSI chip 303 and the silicon capacitor microphone chip 305. Specifically, the ring-shaped resin sheet 337 is composed of an anisotropic conductive film (ACF) having conductivity in the thickness direction and an insulating ability along the surface thereof.

The anisotropic conductive film is formed by incorporating conductive particles having conductivity into a resin material which is softer than the LSI chip 303 and the silicon capacitor microphone chip 305. The resin material is composed of epoxy resin or polyimide resin, and the conductive particles are composed of plastic particles or Ni particles subjected to gold plating or silver plating, for example.

The LSI chip 303 and the silicon capacitor microphone chip 305 are adhered together without a gap therebetween by means of the resin material forming the ring-shaped resin sheet 337. The connection terminals 309 and the connection terminals 335 are electrically connected together via the conductive particles included in the ring-shaped resin sheet 337.

When the LSI chip 303 and the silicon capacitor microphone chip 305 are vertically joined together, a hollow cavity S1 is formed between the diaphragm 329 and the LSI chip 303. The cavity S1 includes a gap formed between the prescribed area of the surface 303a of the LSI chip 303 and the prescribed area of the backside 305b of the silicon capacitor microphone chip 305, which are defined by the ring-shaped resin sheet 337, and the recess 333 recessed downwardly from the surface 303a of the LSI chip 303. Since the LSI chip 303 and the silicon capacitor microphone chip 305 are adhered together without a gap by means of the ring-shaped resin sheet 337, the cavity S1 is closed in an airtight manner and does not communicate with the external space of the semiconductor device 301.

The shield case 307 entirely covers the LSI chip 303 and the silicon capacitor microphone chip 305. Specifically, the shield case 307 includes the stage 341 having a rectangular shape, in which the LSI chip 303 is mounted on a surface 341a, a top portion 343, which is positioned opposite to the surface 305a of the silicon capacitor microphone chip 305, and side walls 345, which extend upwardly from the side ends of the stage 341 to the side ends of the top portion 343 so as to embrace the side portions of the LSI chip 303 and the silicon capacitor microphone chip 305.

An opening 343a is formed approximately at the center of the top portion 343 so as to expose the diaphragm 329 of the silicon capacitor microphone chip 305 to the exterior of the semiconductor device 301. A plurality of heat-dissipation holes 345a are formed on the side walls 345 so as to dissipate heat from the inside to the outside of the shield case 307. Thus, it is possible to efficiently dissipate heat generated by the LSI chip 303 and the silicon capacitor microphone chip 305 to the exterior of the shield case 307 via the heat-dissipation holes 345a.

A plurality of through holes 341c are formed and run through the stage 341 in the thickness direction so as to expose the connection terminals 309 of the LSI chip 303 to the exterior.

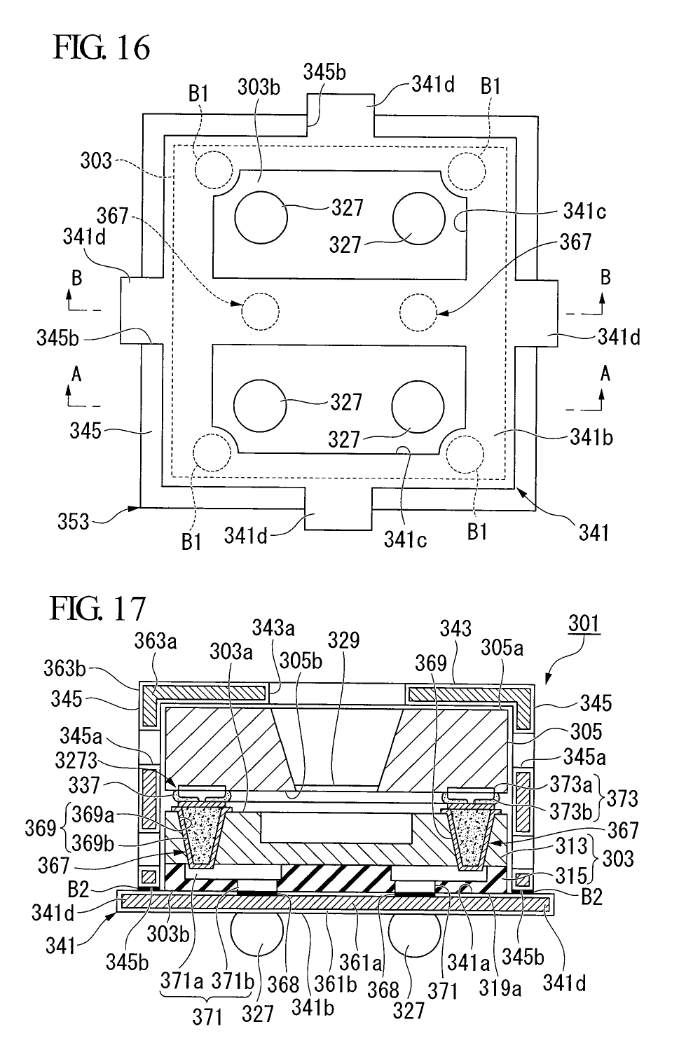

As shown in FIG. 16 and FIG. 14, which is a cross-sectional view taken along line A-A in FIG. 16, a plurality of recesses 319aare formed and recessed from the backside 303b of the LSI chip 303, wherein they are positioned opposite to the surface 341a of the stage 341 except the formation regions of the through holes 341c. The recesses 319aare formed in the insulating layer 319. When the LSI chip 303 is combined with the stage 341, the prescribed portions of the stage 341 are inserted into the recesses 319a. Hence, the thickness of the recess 319ais substantially identical to the depth of the recess 319a. This prevents the stage 341 from projecting downwardly from the backside 303b of the LSI chip 303.

The LSI chip 303 and the stage 341 are fixed together by applying an adhesive B1 between the bottom of the recess 319a(which forms the backside 303b of the LSI chip 303) and the surface 341a of the stage 341. As shown in FIG. 16, the adhesive B1 is applied to four comers of the backside 303b of the LSI chip 303.

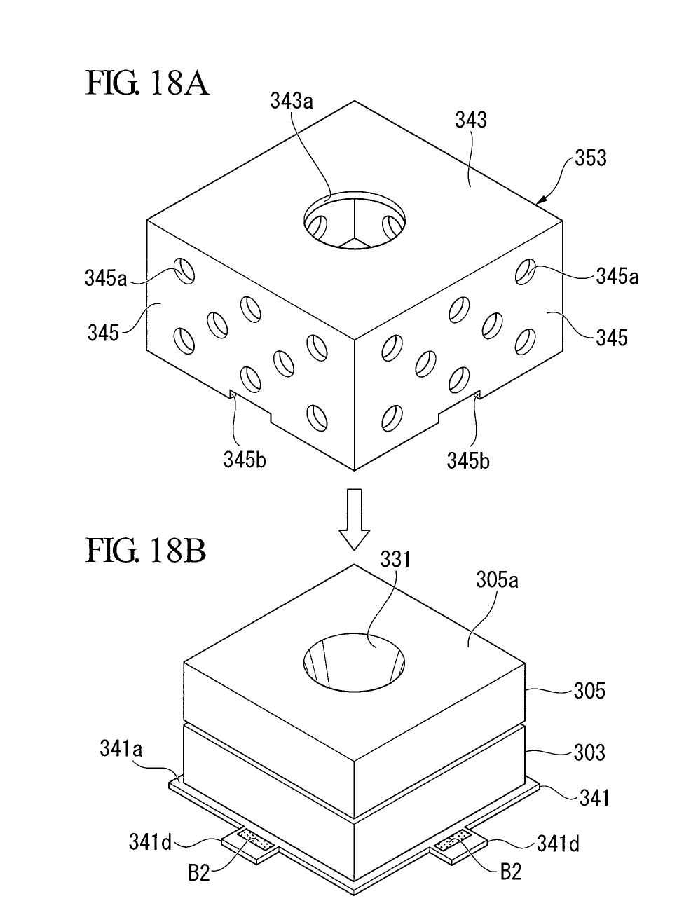

The shield case 307 is constituted of the engagement of two pieces. Specifically, as shown in FIG. 14 and FIGS. 18A and 18B, the stage 341 is constituted of a lower shield member (including the stage 341) and the cover member 353 including the top portion 343 and the side walls 345, wherein the stage 341 is engaged with the cover member 353.

Specifically, a plurality of projections 341d, which horizontally project from the periphery of the surface 341 a of the stage 341 (forming the lower shield member), and a plurality of recesses 345b are correspondingly formed in the tip ends of the side walls 345, which are elongated downwardly from the periphery of the top portion 343 of the cover member 353, so that the projections 341dare respectively engaged with the recesses 345b. When the stage 341 and the cover member 353 are engaged with each other, the lower ends of the side walls 345 are positioned at the four sides of the stage 341.

When they are engaged with each other, the surfaces of the projections 341d, which are positioned in the same plane as the surface 341a of the stage 341, are brought into contact with the bottoms of the recesses 345b, wherein an adhesive B2 is applied to the surfaces of the projections 341dand the bottoms of the recesses 345b respectively, whereby it is possible to reinforce the fixing strength between the stage 341 and the cover member 353 (see FIG. 17).

The internal capacity of the cover member 353 is determined to suit the LSI chip 303 and the silicon capacitor microphone chip 305, which are vertically joined together. That is, the top portion 343 of the cover member 353 is positioned opposite to the surface 305a of the silicon capacitor microphone chip 305 with a small gap therebetween, while the side walls 345 of the cover member 353 are positioned opposite to the side portions of the LSI chip 303 and the silicon capacitor microphone chip 305 with small gaps therebetween.

The stage 341 is formed by coating the surface of a conductive member 361a (having the aforementioned shape) with an insulating film 361b, and the cover member 353 is formed by coating the surface of a conductive member 363a (having the aforementioned shape) with an insulating film 363b. Specifically, the conductive members 361a and 363a composed of aluminum are subjected to alumite treatment so as to form the insulating films 361b and 363b. The alumite treatment is performed after the conductive member 361a is shaped to suit the stage 341, and the conductive member 363a is shaped to suit the cover member 353. Hence, the interior surfaces of the through holes 341cof the stage 341 are coated with the insulating film 261b, while the interior surface of the opening 343a of the top portion 343 and the interior surfaces of the heat-dissipation holes 345a of the side walls 345 are coated with the insulating film 363b.

When the stage 341 is engaged with the cover member 353, the prescribed areas of the projections 341dof the conductive member 361a slide along the prescribed areas of the recesses 345b of the conductive member 363a so that the insulating films 361b and 363b are removed from those areas. This brings the projections 341dand the recesses 345b into direct contact with each other. That is, the conductive member 361a of the stage 341 is electrically connected to the conductive member 363a of the cover member 353.

In addition, the conductive member 361a of the stage 341 is electrically connected to the ground pattern of the substrate (not shown) via ground terminals formed in the LSI chip 303. As shown in FIGS. 16 and 17, a plurality of ground terminals 367 are formed on the bottoms of the recesses 319ain the backside 303b of the LSI chip 303; hence, the prescribed portions of the conductive member 361a are exposed on the surface 341a of the stage 341 at the prescribed positions opposite to the ground terminals 367, so that the conductive member 361 a is electrically connected to the ground terminals 367. Specifically, the exposed portions of the conductive member 361a are electrically connected to the ground terminals 367 via a conductive adhesive 368.

The prescribed portions of the conductive member 361a are exposed by way of masking, by which they are not coated with the insulating film 361b during the alumite treatment.

Similar to the connection terminals 309, the ground terminals 367 are constituted of vias 369, in which metal wires 369bare embedded in the through holes 369a, and wiring portions 371 including re-wiring layers 371a and copper posts 371b. They form electrodes, which run through the LSI chip 303 from the backside 303b to the surface 303a, which is positioned opposite to the silicon capacitor microphone chip 305.

A plurality of ground terminals 373 are formed on the backside 305b of the silicon capacitor microphone chip 305, which is positioned opposite to the surface 303a of the LSI chip 303, and is electrically connected to the ground pattern of the substrate. Similar to the connection terminals 335 of the silicon capacitor microphone chip 305, the ground terminals 373 are constituted of electrode pads 373a and stud bumps 373b and are electrically connected to the ground terminals 367 via the ring-shaped resin sheet 337.

The ground terminals 367 are electrically connected to the connection terminals 309, which serve as ground terminals and are electrically connected to the ground pattern of the substrate. That is, the conductive member 361a of the stage 341 is electrically connected to the ground pattern of the substrate via the ground terminals 367 and the connection terminals 309.

In the manufacturing of the semiconductor device 301, the silicon capacitor microphone chip 305 is attached onto the surface 303a of the LSI chip 303, whereby the silicon capacitor microphone chip 305 and the LSI chip 303 are fixed together by way of adhesion and are electrically connected together. This is called a chip joining step.

In the chip joining step, the ring-shaped resin sheet 337 is positioned in the periphery of the recess 333 and is temporarily fixed onto the surface 303a of the LSI chip 303. Herein, the ring-shaped resin sheet 337 is positioned above the metal wires 317b of the vias 317 and the metal wires 369bof the vias 369. Simultaneously with the temporary fixing of the ring-shape resin sheet 337, or before or after the temporary fixing of the ring-shaped resin sheet 337, the stud bumps 335b and 337b are formed on the electrode pads 335a and 373a formed on the backside 305b of the silicon capacitor microphone chip 305, thus forming the connection terminals 335 and the ground terminals 373.

Next, the silicon capacitor microphone chip 305 is attached onto the surface 303a of the LSI chip 303 in such a way that the connection terminals 335 and the ground terminals 373 are positioned opposite to the vias 317 and 369.

In the above, the ring-shaped resin sheet 337 is heated while pressure is applied to the silicon capacitor microphone chip 305, whereby the resin material of the ring-shaped resin sheet 337 is melted so that the stud bumps 335b of the connection terminals 335 and the stud bumps 373b of the ground terminals 373 move downwardly into the ring-shaped resin sheet 337, whereby the conductive particles of the ring-shaped resin sheet 337 are sandwiched between the metal wires 317b and 369band the stud bumps 335b and 373b, which are positioned opposite to each other. Thus, the LSI chip 303 and the silicon capacitor microphone chip 305 are fixed together by way of adhesion, wherein the connection terminals 309 and 335 are electrically connected together, and the ground terminals 367 and 373 are electrically connected together, thus completing the chip joining step.

After completion of the chip joining step, a chip fixing step is performed so as to fix the LSI chip 303 onto the surface 341a of the stage 341. In this step, the stage 341 except for the prescribed regions forming the through holes 341cis engaged with the recesses 319aof the LSI chip 303, whereby the connection terminals 309 are exposed to the exterior via the through holes 341c of the stage 341.

In this step, the ground terminals 367, which are formed on the bottoms of the recesses 319a, are brought into contact with and are electrically connected to the prescribed portions of the conductive member 361, which are exposed onto the surface 341a of the stage 341, via the conductive adhesive 368.

Lastly, a case engaging step is performed in such a way that the LSI chip 303 and the silicon capacitor microphone chip 305 vertically joined together are covered with the cover member 353 and are engaged with the stage 341, thus completing the manufacturing of the semiconductor device 301.

In the case engaging step, the projections 341dof the stage 341 slide along the recesses 345b of the cover member 353 so that the insulating films 361b and 363 are partially removed, thus bringing the conductive member 361a of the stage 341 into direct contact with the conductive member 363a of the cover member 353.

When the semiconductor device 301 is mounted on the substrate, both of the backside 341b of the stage 341 and the backside 303b of the LSI chip 303 are positioned opposite to the surface of the substrate; then, in the condition in which the solder balls 327 are brought into contact with the electrode pads of the substrate (not shown), the semiconductor device 301 is pressed toward the substrate while the solder balls 327 are heated. Thus, the semiconductor device 301 is fixed onto the surface of the substrate, wherein the LSI chip 303 and the silicon capacitor microphone chip 305 are electrically connected to the substrate.

When sound pressure variations are transmitted to the diaphragm 329 of the silicon capacitor microphone chip 305 via the opening 343a of the cover member 309 of the shield case 307, the diaphragm 329 vibrates in response to sound pressure variations, thus making it possible for the semiconductor device 301 to detect sound pressure variations.

The semiconductor device 301 is advantageous in that, by simply establishing electrical connection between the connection terminals 309 (forming the electrodes running through the LSI chip 303) and the substrate, the LSI chip 303 and the silicon capacitor microphone chip 305 vertically joined together are electrically connected to the substrate. This eliminates the necessity of individually mounting the silicon capacitor microphone chip 305 and the LSI chip 303 on the substrate. Therefore, it is possible to downsize the semiconductor device 301 with ease; and it is possible to reduce the mounting area of the semiconductor device 301 mounted on the surface of the substrate. That is, the semiconductor device 301 can be adapted to the chip size package with ease.

By electrically connecting the conductive members 361a and 363a (forming the shield case 307) to the ground pattern of the substrate, it is possible to form an electromagnetic shield for preventing electromagnetic noise from being transmitted into the shield case 307 from the external space. This reliably prevents electromagnetic noise from being transmitted to the LSI chip 303 and the silicon capacitor microphone chip 305. Thus, it is possible to reliably avoid the occurrence of operational errors of the LSI chip 303 and the silicon capacitor microphone chip 305 due to electromagnetic noise.

The conductive members 361a and 363a are electrically connected to the substrate via the ground terminals 367 and the connection terminals of the LSI chip 303; hence, by simply mounting the semiconductor device 301 on the substrate, it is possible to easily establish electrical connection between the conductive members 361a and 363a and the substrate, and it is possible to easily form the electromagnetic shield.

The electrical connection between the ground terminals 367 and the conductive members 361a is realized in substantially the same plane as the surface 341a of the stage 341. Even though the LSI chip 303 and the stage 341 are heated when the semiconductor device 301 is mounted on the substrate, it is possible to prevent stress, which occurs due to differences of thermal expansion coefficients between the LSI chip 303 and the stage 341, from occurring on the ground terminals 367. Thus, it is possible to reliably maintain the electrical connection between the ground terminals 367 and the conductive member 361a.

The present embodiment is characterized in that the LSI chip 303 and the silicon capacitor microphone chip 305 vertically joined together are completely held inside of the shield case 307. This makes it easy to secure mechanical protection with respect to the LSI chip 303 and the silicon capacitor microphone chip 305. The capacity of the shield case 307 is determined so as to substantially match the total volume of the LSI chip 303 and the silicon capacitor microphone chip 305; hence, it is possible to prevent the size of the semiconductor device 301 from being increased.

In the shield case 307, the conductive members 361a and 363a are coated with the insulating films 361b and 363b. Hence, even when the internal capacity of the shield case 307 is reduced, it is possible to easily prevent the electronic circuits of the LSI chip 303 and the silicon capacitor microphone chip 305 from being short-circuited due to the shield case 307.

The shield case 307 is formed by means of the stage 241 and the cover member 353, which are engaged with each other. This makes it possible for the cover member 353 to be engaged with the stage 341 after the LSI chip 303 and the silicon capacitor microphone chip 305 are mounted on the surface 341a of the stage 341. That is, after the silicon capacitor microphone chip 305 is vertically joined to the LSI chip 303 on the stage 341, the cover member 353 is precisely positioned so that the surface 305a of the silicon capacitor microphone chip 305 is covered with the top portion 343. This makes it easy for the LSI chip 303 and the silicon capacitor microphone chip 305 vertically joined together to be mounted on the stage 341. In short, it is possible to manufacture the semiconductor device 301 with ease.

When the LSI chip 303 is mounted on the surface 341a of the stage 341, the stage 341 is partially engaged with the recesses 319aof the insulating layer 319 of the LSI chip 303. This makes it easy to establish precise positioning of the LSI chip 303 relative to the stage 341. Due to the engagement between the prescribed portions of the stage 341 and the recesses 391a of the insulating layer 319 of the LSI chip 303, it is possible to reduce the height of the LSI chip 303 measured from the surface 341a of the stage 341; hence, it is possible to reduce the thickness of the semiconductor device 301 with ease.

In addition, the backside 341b of the stage 341, which is engaged with the recesses 319aof the insulating layer 319 of the LSI chip 303, does not project downwardly from the backside of the LSI chip 303; hence, it is possible to reduce the sizes of the solder balls 327 attached onto the backside 303b of the LSI chip 303. This reduces the pitch between the adjacent solder balls 327. That is, due to the reduced pitch between the adjacent solder balls 327, it is possible to downsize the LSI chip 303. This realizes a further downsizing of the semiconductor device 301.

The volume of the cavity S1, which is closed in an airtight manner by means of the ring-shaped resin sheet 337 and is formed between the diaphragm 329 and the LSI chip 303, can be easily determined in accordance with the dimensions and shape of the ring-shaped resin sheet 337, which is formed in advance. That is, during the manufacturing of the semiconductor device 301, it is possible to prevent the volume of the cavity S1 from being unexpectedly changed; and it is possible to prevent the vibration characteristic of the diaphragm 329 from being unexpectedly changed. Thus, it is possible to improve the yield and manufacturing efficiency with respect to the semiconductor device 301.

In addition, the volume of the cavity S1 can be easily increased by way of the formation of the recess 333 in the LSI chip 303. This allows the diaphragm 329 to easily vibrate. Therefore, it is possible to accurately detect sound pressure variations by way of the vibration of the diaphragm 329.

This eliminates the necessity of additionally forming a recess in the substrate in order to increase the cavity S1; and it is unnecessary to increase the thickness of the substrate in order to secure the required rigidity. Hence, it is possible to reduce the thickness of the substrate for mounting the semiconductor device 301 thereon with ease.

The present embodiment is characterized in that an anisotropic conductive film is used for the ring-shaped resin sheet 337 for realizing the adhesion between the LSI chip 303 and the silicon capacitor microphone chip 305. The anisotropic conductive film allows the metal wires 317b of the vias 317 to be electrically connected to the connection terminals 335; and it also allows the metal wires 367b of the vias 367 to be electrically connected to the ground terminals 373. In short, the vias 317 and 367 electrically join the connection terminals 335 and the ground terminals 373 by way of the anisotropic conductive film. This eliminates the necessity of individually preparing another joining material for joining the vias 317, the connection terminals 335, and the ground terminals 373 together. Thus, it is possible to establish electrical connection between the vias 317, the connection terminals 335, and the ground terminals 373 with ease.

Due to the use of the anisotropic conductive film, it is possible to prevent the adjacent vias 317 from being electrically connected together on the surface 303a of the LSI chip 303; and it is possible to prevent the adjacent vias 367 from being electrically connected together on the surface 303a of the LSI chip 303. In addition, it is possible to prevent the adjacent connection terminals 335 from being electrically connected together on the backside 305b of the silicon capacitor microphone chip 305; and it is possible to prevent the adjacent ground terminals 373 from being electrically connected together on the backside 305b of the silicon capacitor microphone chip 305. Thus, it is possible to reduce the pitch between the adjacent vias 317; it is possible to reduce the pitch between the adjacent vias 367; it is possible to reduce the pitch between the adjacent connection terminals 335; and it is possible to reduce the pitch between the adjacent ground terminals 373. This further downsizes the LSI chip 303 and the silicon capacitor microphone chip 305.

Furthermore, the resin material of the anisotropic conductive film, which realizes the adhesion between the LSI chip 303 and the silicon capacitor microphone chip 305, is softer than the LSI chip 303 and the silicon capacitor microphone chip 305; hence, it is possible to reduce the stress, which occurs between the LSI chip 303 and the silicon capacitor microphone chip 305 adhering together, by way of the deformation of the ring-shaped resin sheet 337.

The manufacturing method of the semiconductor device 301 includes the chip joining step and the chip fixing step, by which the LSI chip 303 and the silicon capacitor microphone chip 305 are vertically joined together on the surface 341a of the stage 341. Then, the case engaging step is performed so that the LSI chip 303 and the silicon capacitor microphone chip 305 vertically joined together are stored inside of the shield case 307, thus completing the production of the semiconductor device 301 in which the connection terminals 309 are exposed externally of the LSI chip 303.

In the case engaging step, the prescribed portions of the insulating films 361b and 363b coating the projections 341dand the recesses 345b are removed so that the conductive member 361a of the stage 341 is brought into direct contact with and electrically connected to the conductive member 363a of the cover member 353. In other words, the shield case 307 is produced with ease in such a way that the surfaces of the conductive members 361a and 363a, which are electrically joined together, are coated with the insulating films 361b and 363b.

As described above, the present embodiment improves the manufacturing efficiency of the semiconductor device 301.

The present embodiment can be modified in a variety ways, which will be described below.

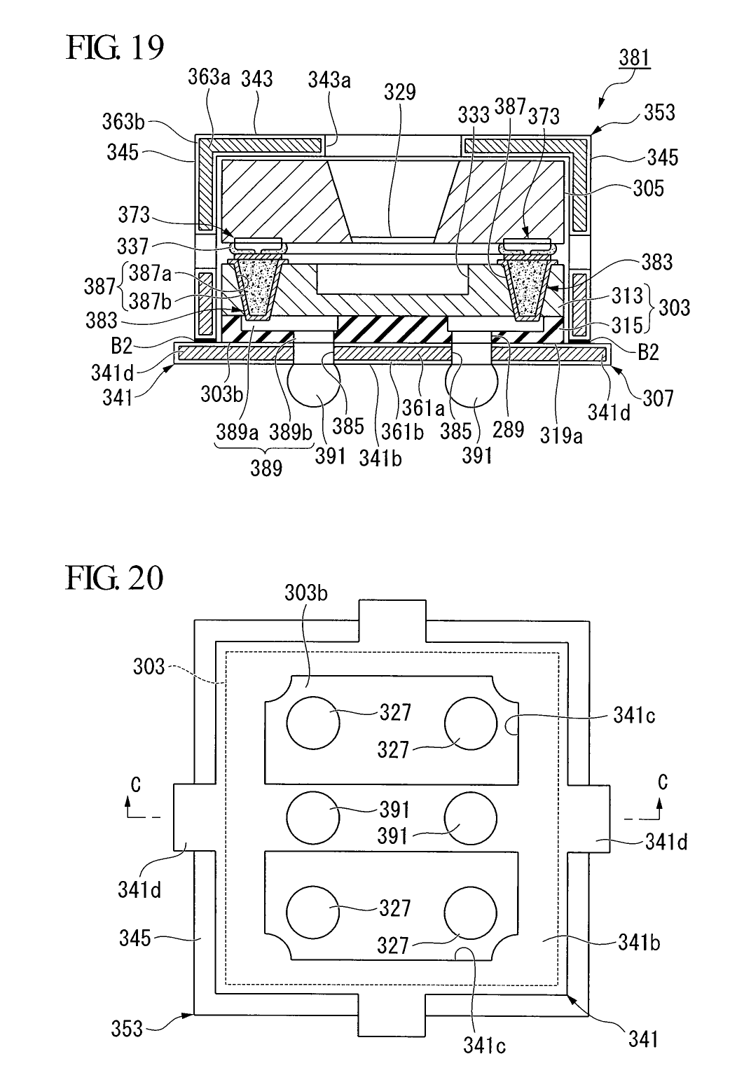

With reference to FIGS. 19 and 20, a semiconductor device 381 will be described in accordance with a first variation of the third embodiment. The semiconductor device 381 differs from the semiconductor device 301 with respect to the structure regarding ground terminals, wherein parts identical to those of the semiconductor device 301 are designated by the same reference numerals; hence, the detailed description thereof will be omitted as necessary.

FIG. 19 is a cross-sectional view taken along line C-C in FIG. 19. In the semiconductor device 381, ground terminals 383 are inserted into through holes 385, which are formed in the stage 341. Similar to the ground terminals 367, the ground terminals 383 include vias 387, in which metal wires 387b are embedded in through holes 387a, and wiring portions 389b, which are constituted of re-wiring layers 389aand wiring posts 389b, wherein the wiring posts 389bare configured identical to the copper posts 371b. The lower ends of the wiring posts 389bproject downwardly from the bottoms of the recesses 319ain the backside 303b of the LSI chip 303, wherein the exterior surfaces of the projected portions of the wiring posts 389bcome in contact with the interior surfaces of the through holes 385 of the stage 341.

The conductive member 361a of the stage 341 is partially exposed onto the interior surfaces of the through holes 385; hence, the conductive member 361a is electrically connected to the ground terminals 383. The partially exposed portions of the conductive member 361a are formed by forming the through holes 385 after completion of the alumite treatment for forming the insulating film 361b, for example.

The lower ends of the wiring posts 389b, which are inserted into the through holes 385, are formed in substantially the same plane as the backside 341b of the stage 341 and are attached with solder balls 391, which are similar to the aforementioned solder balls attached to the connection terminals 309. Incidentally, the projected portions of the wiring posts 389bcan be formed by filling the through holes 385 with a conductive material such as solder after the LSI chip 303 is mounted on the stage 341.

In the manufacturing of the semiconductor device 381, the aforementioned chip joining step and the chip fixing step are performed first. After the LSI chip 303 is mounted on the stage 341 in such a way that the prescribed portions of the stage 341 are engaged with the recesses 319aof the LSI chip 303, the through holes 385 are filled with the conductive material such as solder so as to form the wiring posts 389b, so that the ground terminals 383 are brought into contact with and electrically connected to the exposed portions of the conductive member 361a of the stage 341, which are exposed on the interior surfaces of the through holes 385.

After completion of the chip fixing step, the aforementioned case engaging step is performed, thus completing the manufacturing of the semiconductor device 381.

The semiconductor device 381 demonstrates effects similar to the aforementioned effects of the semiconductor device 301. That is, it is possible to reliably establish electrical connection between the conductive members 361a and 363a and the ground pattern of the substrate by electrically connecting the ground terminals 383 to the ground pattern of the substrate via the solder balls 391 when the semiconductor device 381 is mounted on the substrate; hence, it is possible to form an electromagnetic shield with ease.

The semiconductor device 381 is characterized in that the ground terminals 383 are electrically connected to both of the conductive member 361a and the ground pattern of the substrate. Compared with the semiconductor device 301, the semiconductor device 381 is advantageous because it does not need the connection terminals 309 serving as the ground terminals. In other words, it is possible to minimize the number of ground terminals formed in the LSI chip 303; hence, it is possible to further reduce the size of the LSI chip 303.

The third embodiment and its first variation are respectively directed to the semiconductor devices 301 and 381, each of which includes the LSI chip 303 and the silicon capacitor microphone chip 305 both having substantially the same size; but this is not a restriction. That is, they can be adapted to a semiconductor device including the LSI chip 303 and the silicon capacitor microphone chip 305 having different sizes.

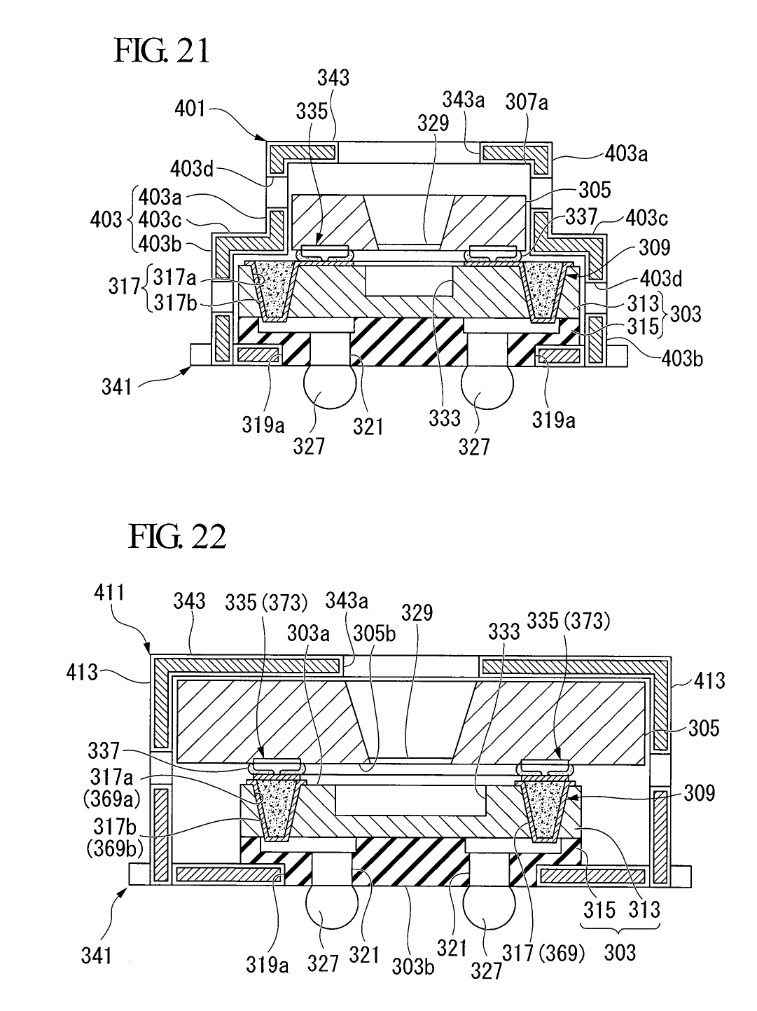

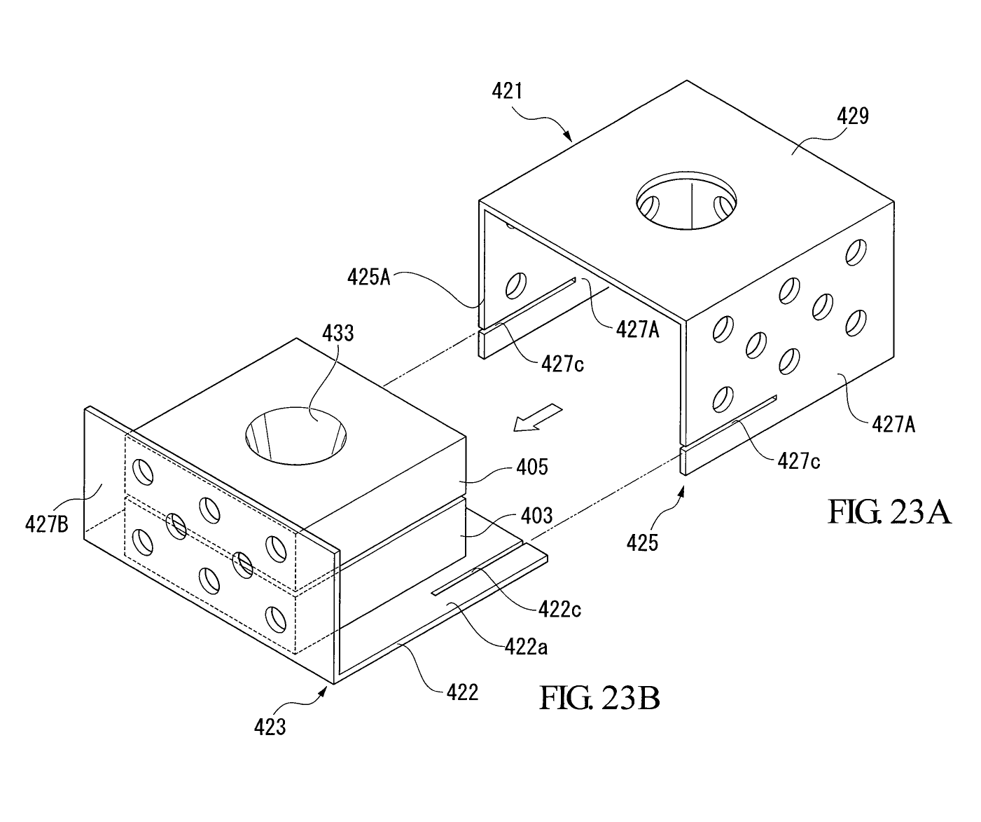

FIG. 21 shows a second variation of the third embodiment, wherein parts identical to those shown in the semiconductor device 301 are designated by the same reference numerals; hence, the detailed description thereof will be omitted as necessary. Herein, the silicon capacitor microphone chip 305 is reduced in size in comparison with the LSI chip 303; that is, the side portions of the LSI chip 303 extend outwardly from the side portions of the silicon capacitor microphone chip 305 in plan view.

In the above, a specially-designed cover member 401 whose side walls 403 are shaped to cover the LSI chip 303 and the silicon capacitor microphone chip 305 vertically joined together by way of the formation of a ring-shaped step portion 403c, whereby the side walls 403 are positioned opposite to the side portions of the silicon capacitor microphone chip 305 with a small gap therebetween and are also positioned opposite to the side portions of the LSI chip 303 with a small gap therebetween.

Specifically, the cover member 401 includes a small-diameter portion 403a having a cylindrical shape, which is positioned so as to embrace the silicon capacitor microphone chip 305 with a small gap therebetween and a large-diameter portion 403b having a cylindrical shape, which is positioned so as to embrace the LSI chip 403 with a small gap therebetween as well as the ring-shaped step portion 403c for interconnecting the small-diameter portion 403a and the large-diameter portion 403b. In addition, a plurality of heat-dissipation holes 403d are formed in the small-diameter portion 403a and the large-diameter portion 403b.

When the silicon capacitor microphone chip 305 is smaller than the LSI chip 303, the connection terminals 335 are shifted in position slightly away from the through holes 317a. To cope with such a positional deviation, the metal wires 317b are elongated horizontally from the through holes 317a toward the connection terminals 335 along the surface 303a of the LSI chip 303. In this case, the metal wires 317b are not necessarily formed in the through holes 317a to lie in the thickness direction of the LSI chip 303.

FIG. 21 does not show that the ground terminals 373 of the silicon capacitor microphone chip 305 are shifted in position slightly away from the positions of the through holes 369aforming the ground terminals 367; however, to cope with such a positional deviation, the metal wires 369bare elongated horizontally from the through holes 369atoward the ground terminals 373.

FIG. 22 shows a third variation of the third embodiment, wherein parts identical to those of the semiconductor device 301 are designated by the same reference numerals; hence, the description thereof will be omitted as necessary. Herein, the silicon capacitor microphone chip 305 is increased in size in comparison with the LSI chip 303; that is, the side portions of the silicon capacitor microphone chip 305 extend outwardly from the side portions of the LSI chip 303 in plan view. A newly-designed cover member 411 is provided so as to cover the silicon capacitor microphone chip 305 and the LSI chip 303 vertically joined together in such a way that side walls 413 are positioned opposite to the side portions of the silicon capacitor microphone chip 305 with a small gap therebetween. In this structure, the side walls 413 of the cover member 411 are positioned opposite to the side portions of the LSI chip 303 with a relatively large gap therebetween.

In the above, the connection terminals 335 and the ground terminals 373, which are formed on the backside 305a of the silicon capacitor microphone chip 305, should be precisely positioned opposite to the metal wires 317b and 369bformed on the surface 303a of the LSI chip 303.

In the present embodiment, the shield case 307 is formed in such a way that the cover member 353 moves downwardly so as to cover the upper portion of the stage 341; but this is not a restriction. That is, the present embodiment simply requires that the shield case 307 be constituted by a cover member and a mount member, which can be engaged with each other. For example, it is possible to introduce a shield case 421 constituted of a cover member 425 and a mount member 423 including a stage 422 having a rectangular shape, wherein the cover member 425 is moved horizontally toward the prescribed side of the mount member 423, so that the cover member 425 is engaged with the mount member 423. The cover member 425 has three side walls 427A at three sides thereof, so that the remaining side is opened so as to realize the engagement with the mount member 423.

Specifically, two slits 422c are formed in the stage 422 and are elongated horizontally along its surface 422a, while two slits 427c are formed in the two side walls 427A, which are opposite to each other, and are elongated horizontally. The cover member 425 and the mount member 423 are engaged with each other upon engagement of the slits 422c and 427c. In this structure, when the slits 422c and 427c are brought in contact with each other and are thus engaged with each other, insulating films formed inside of the slits 422c and 427c are removed due to the sliding movement. This establishes electrical connection between the conductive members forming the cover member 425 and the stage 422, respectively.

As described above, the LSI chip 303 and the silicon capacitor microphone chip 305, which are vertically joined together on the stage 422, are moved horizontally and are inserted into the internal space of the cover member 425. The cover member 425 is formed by integrally forming a top portion 429 together with the three side walls 427A, thus forming an opening 425A allowing the LSI chip 303 and the silicon capacitor microphone chip 305 to be inserted into the internal space of the cover member 425. In addition, another side wall 427B is integrally formed together with the stage 422 so as to form the mount member 423. Thus, when the cover member 425 is engaged with the mount member 423, the opening 425A is closed by the side wall 427B so that the LSI chip 303 and the silicon capacitor microphone chip 305 are surrounded by the top portion 429, the three side walls 427A, the side wall 427B, and the stage 422.

In the manufacturing of the present embodiment, the chip fixing step is performed after the chip joining step; but this is not a restriction. That is, it is possible to perform the chip joining step, in which the silicon capacitor microphone chip 305 is vertically joined to the LSI chip 303, after completion of the chip fixing step, in which the LSI chip 303 is fixed onto the surface 341 a of the stage 341.

The depth of the recess 319aof the insulating layer 319 (forming the LSI chip 303) is not necessarily identical to the thickness of the stage 341. That is, the depth of the recess 319acan be increased so as to be larger than the thickness of the stage 341. In this structure, the stage 341 does not project downwardly from the backside 303b of the LSI chip 303. Hence, it is possible to reduce the size of the solder ball 327 in comparison with the conventionally-known structure in which the stage 341 projects downwardly from the backside 303b of the LSI chip 303.

In the present embodiment, the solder balls 327 and 391 project from the backside 303b of the LSI chip 303; but this is not a restriction. The present embodiment simply requires that connection terminals be formed on the backside 303b so as to establish electrical connection between the LSI chip 303 and the substrate. That is, instead of the solder balls 327 and 391, the copper posts 321b and/or the wiring posts 389bproject from the backside 303b of the LSI chip 303.

The LSI chip 303 is not necessarily constituted of the main unit 313 and the wiring package unit 315. That is, the LSI chip 303 can be formed by the main unit 313 only. In this structure, the connection terminals 309 and the ground terminals 367 and 383, all of which serve as the electrodes running through the LSI chip 303, are formed using the vias 317, 369, and 387 only.

The ring-shaped resin sheet 337 is not necessarily composed of an anisotropic conductive film. The present embodiment simply requires that the ring-shaped resin sheet 337 be composed of a resin material which is softer than the LSI chip 303 and the silicon capacitor microphone chip 305. In this structure, it is preferable that the connection terminals 309 and 335 be joined together via an additional joining material such as solder and conductive adhesive. The conductive adhesive is mainly composed of a resin material such as epoxy resin.

When the connection terminals 309 and 335 are joined together via the solder, the solder is printed on the upper ends of the vias 317, 369, and 387, which are exposed on the surface 303a of the LSI chip 303, in advance; then, the ring-shaped resin sheet 337 is temporarily fixed onto the surface 303a of the LSI chip 303. Next, the silicon capacitor microphone chip 305 is attached onto the surface 303a of the LSI chip 303; then, the ring-shaped resin sheet 337 and the solder are heated while pressure is applied to the silicon capacitor microphone chip 305.

In the above, the stud bumps 335b and 373b move downwardly into the ring-shaped resin sheet 337 and come in contact with the solder. Due to the heating, the solder is melted as well, so that the stud bumps 335b and 373b join the vias 317, 369, and 387 via the solder.

When the connection terminals 309 and 335 are joined together via the conducive adhesive, the conductive adhesive is applied to the stud bumps 335b and 373b of the silicon capacitor microphone chip 305 in advance; then, the ring-shaped resin sheet 337 is temporarily fixed to the surface 303a of the LSI chip 303. Next, the silicon capacitor microphone chip 305 is attached onto the surface 303a of the LSI chip 303; then, the ring-shaped resin sheet 337 and the conductive adhesive are heated while pressure is applied to the silicon capacitor microphone chip 305.

In the above, the stud bumps 335b and 373b move downwardly into the ring-shaped resin sheet 337 and come in contact with the conductive adhesive. Due to the heating, the resin material included in the conductive adhesive is melted as well, so that the stud bumps 335b and 373b join the vias 317, 369, and 387 via the conductive adhesive.

In the present embodiment, the recess 333, which is opposite to the diaphragm 329, is formed and recessed downwardly from the surface 303a of the LSI chip 303; but this is not a restriction. The present embodiment simply requires that a gap having a certain volume within the cavity S1 be formed between the surface 303a of the LSI chip 303 and the backside 305b of the silicon capacitor microphone chip 305 so as to accurately detect sound pressure variations by way of the vibration of the diaphragm 329; that is, the recess 333 is not necessarily formed in the LSI chip 303.

The silicon capacitor microphone chip 305 is not necessarily designed as the sound pressure sensor chip equipped with the diaphragm 329. It is simply required that the silicon capacitor microphone chip 305 be designed to have a movable part such as the diaphragm 329. That is, the silicon capacitor microphone chip 305 can be designed as the pressure sensor for detecting pressure variations occurring in the external space of the semiconductor device 301 or 381, for example.

Lastly, the present invention is not necessarily limited by the aforementioned embodiments and variations, wherein the scope of the invention is defined by the appended claims; hence, further variations and modifications can be realized within the scope of the invention.

1. A semiconductor device comprising:
a substrate;
a semiconductor chip having a diaphragm, which vibrates in response to pressure variations; and
a circuit chip that is electrically connected to the semiconductor chip so as to control the semiconductor chip,
wherein the semiconductor chip is positioned opposite to and fixed to a surface of the circuit chip whose backside is attached onto a surface of the substrate.

2. A semiconductor device according to claim 1, wherein a recess is formed and recessed from the surface of the circuit chip so that an opening thereof is positioned opposite to the diaphragm.

3. A semiconductor device according to claim 1, wherein a plurality of connection terminals are formed on the backside of the circuit chip so as to establish electrical connection with the substrate.

4. A semiconductor device according to claim 1, wherein a plurality of connection terminals are formed on the surface of the circuit chip and on a backside of the semiconductor chip, which is positioned opposite to the surface of the circuit chip, so as to establish an electrical connection between the circuit chip and the semiconductor chip.

5. A semiconductor device according to claim 1, wherein a plurality of connection terminals are formed on the backside of the circuit chip so as to establish an electrical connection with the substrate, and wherein a plurality of connection terminals are formed on the surface of the circuit chip and on a backside of the semiconductor chip, which is positioned opposite to the surface of the circuit chip, so as to establish an electrical connection between the circuit chip and the semiconductor chip

6. A semiconductor device according to claim 1 further comprising a spacer having a rectangular shape, which is inserted between the semiconductor chip and the circuit chip, wherein an overall area of the spacer is smaller than an overall area of the surface of the circuit chip.

7. A semiconductor device according to claim 1 further comprising a spacer having a rectangular shape, which is inserted between the semiconductor chip and the circuit chip, wherein an overall area of the spacer is smaller than an overall area of the surface of the circuit chip, and wherein a through hole is formed and runs through the spacer in its thickness direction, thus allowing the diaphragm to be positioned opposite to the surface of the circuit chip via the through hole.

8. A semiconductor device according to claim 1 further comprising a spacer having a rectangular shape, which is inserted between the semiconductor chip and the circuit chip, wherein an overall area of the spacer is smaller than an overall area of the surface of the circuit chip, wherein a through hole is formed and runs through the spacer in its thickness direction so as to allow the diaphragm to be positioned opposite to the surface of the circuit chip via the through hole, and wherein a plurality of connection terminals are formed on the backside of the circuit chip so as to establish an electrical connection with the substrate.

9. A semiconductor device according to claim 1 further comprising a spacer having a rectangular shape, which is inserted between the semiconductor chip and the circuit chip, wherein an overall area of the spacer is smaller than an overall area of the surface of the circuit chip, wherein a through hole is formed and runs through the spacer in its thickness direction so as to allow the diaphragm to be positioned opposite to the surface of the circuit chip via the through hole, and wherein a plurality of connection terminals are formed on the surface of the circuit chip and on a backside of the semiconductor chip, which is positioned opposite to the surface of the circuit chip, so as to establish an electrical connection between the circuit chip and the semiconductor chip.

10. A semiconductor device according to claim 1 further comprising a spacer having a rectangular shape, which is inserted between the semiconductor chip and the circuit chip, wherein an overall area of the spacer is smaller than an overall area of the surface of the circuit chip, wherein a through hole is formed and runs through the spacer in its thickness direction so as to allow the diaphragm to be positioned opposite to the surface of the circuit chip via the through hole, wherein a plurality of connection terminals are formed on the backside of the circuit chip so as to establish an electrical connection with the substrate, and wherein a plurality of connection terminals are formed on the surface of the circuit chip and on a backside of the semiconductor chip, which is positioned opposite to the surface of the circuit chip, so as to establish an electrical connection between the circuit chip and the semiconductor chip.

11. A semiconductor device according to claim 1 further comprising
a plurality of electrodes, which run through the circuit chip in its thickness direction from the surface thereof to the backside thereof,
a plurality of connection terminals, which are formed on a backside of the semiconductor chip positioned opposite to the surface of the circuit chip and which are electrically connected to the plurality of electrodes, and
a ring-shaped resin sheet, which is positioned in a surrounding area of the diaphragm and which is inserted between the semiconductor chip and the circuit chip, which are thus joined together without a gap therebetween.

12. A semiconductor device according to claim 11, wherein the ring-shaped resin sheet is composed of a resin material that is softer than the semiconductor chip and the circuit chip.

13. A semiconductor device according to claim 11, wherein the plurality of connection terminals and the plurality of electrodes are positioned opposite to each other, and wherein the ring-shaped resin sheet is composed of an anisotropic conductive film, which has a conductivity in a thickness direction and an insulating ability along a surface thereof, and is positioned between the plurality of connection terminals and the plurality of electrodes.

14. A semiconductor device according to claim 11, wherein a recess is formed and recessed downwardly from the surface of the circuit chip so that an opening thereof is positioned opposite to the diaphragm.

15. semiconductor device according to claim 11 further comprising a cover member that is fixed to a surface of the semiconductor chip so as to cover side portions of the semiconductor chip and side portions of the circuit chip, wherein an opening is formed at a prescribed position of the cover member so as to partially expose the diaphragm to an exterior.

16. A semiconductor device according to claim 11 further comprising a cover member that is fixed to a surface of the semiconductor chip so as to cover side portions of the semiconductor chip and side portions of the circuit chip, wherein an opening is formed at a prescribed position of the cover member so as to partially expose the diaphragm to an exterior, and wherein a recess is formed and recessed downwardly from the surface of the circuit chip so that an opening thereof is positioned opposite to the diaphragm.

17. A semiconductor device according to claim 11 further comprising a cover member, which includes a conductive member coated with an insulating film and which is fixed to a surface of the semiconductor chip so as to cover side portions of the semiconductor chip and side portions of the circuit chip, wherein an opening is formed at a prescribed position of the cover member so as to partially expose the diaphragm to an exterior.

18. A semiconductor device according to claim 11 further comprising a cover member, which includes a conductive member coated with an insulating film and which is fixed to a surface of the semiconductor chip so as to cover side portions of the semiconductor chip and side portions of the circuit chip, wherein an opening is formed at a prescribed position of the cover member so as to partially expose the diaphragm to an exterior, and wherein a recess is formed and recessed downwardly from the surface of the circuit chip so that an opening thereof is positioned opposite to the diaphragm.

19. A semiconductor device according to claim 1 further comprising a shield case for storing the semiconductor chip and the circuit chip therein, wherein the shield case, which is formed by coating a conductive member with an insulating film, includes a stage having a rectangular shape, which the circuit chip is fixed onto, a top portion, which is positioned opposite to a surface of the semiconductor chip and which has an opening allowing the diaphragm to be exposed to an exterior of the shield case, and a plurality of side walls, which are elongated from side ends of the stage to side ends of the top portion so as to surround the semiconductor chip and the circuit chip, which are vertically joined together, and wherein a plurality of through holes are formed in the stage so as to allow a plurality of connection terminals, which are formed on the backside of the circuit chip, to be exposed.

20. A semiconductor device according to claim 19, wherein at least a first ground terminal and a second ground terminal, which are electrically connected to each other, are formed on the backside of the circuit chip, wherein the first ground terminal forms the connection terminal, and wherein the second ground terminal is positioned opposite to a surface of the stage, on which the conductive member is partially exposed and is electrically connected to the second ground terminal.

21. A semiconductor device according to claim 19, wherein a plurality of ground terminals are formed on the backside of the circuit chip and are inserted into a plurality of through holes, in which the conductive member is partially exposed in interior surfaces thereof, so that the ground terminals are brought into contact with and are electrically connected to the conductive member.

22. A semiconductor device according to claim 19, wherein the shield case is constituted of a cover member having the top portion and the plurality of side walls and a mount member having the stage, and wherein the cover member is engaged with the mount member so as to form the shield case.

23. A semiconductor device according to claim 19, wherein a plurality of recesses are formed and recessed from the backside of the circuit chip so as to cover the surface of the stage except for prescribed regions corresponding to the through holes.

24. A semiconductor device according to claim 19, wherein a plurality of heat-dissipation holes are formed on the plurality of side walls so as to dissipate heat generated by the semiconductor chip and/or the circuit chip.

25. A semiconductor device according to claim 19, wherein the semiconductor chip and the circuit chip, which are vertically joined together, are adhered together by means of a ring-shaped resin sheet, which is positioned in a periphery of the diaphragm, without a gap therebetween.

26. A semiconductor device according to claim 19, wherein the semiconductor chip and the circuit chip, which are vertically joined together, are adhered together by means of a ring-shaped resin sheet, which is positioned in a periphery of the diaphragm, without a gap therebetween, and wherein a recess is formed and recessed from the surface of the circuit chip, which is positioned opposite to the diaphragm.

27. A manufacturing method for a semiconductor device, in which a semiconductor chip having a diaphragm and a circuit chip are vertically joined together and are stored in a shield case such that the diaphragm is exposed to an exterior of the shield case, said manufacturing method comprising the steps of:
attaching the semiconductor chip onto a surface of the circuit chip in such a way that the diaphragm is positioned opposite to the circuit chip, thus fixing and electrically connecting together the semiconductor chip and the circuit chip;
fixing the circuit chip onto a surface of a stage having a rectangular shape included in a mount member of the shield case, in which an insulating film is coated on a surface of a conductive member, thus exposing a plurality of connection terminals, which are formed on a backside of the circuit chip, to an exterior of the mount member via a plurality of through holes, which are formed in the stage; and
covering the semiconductor chip and the circuit chip, which are vertically joined together, with a cover member of the shield case, in which an insulating film is coated on a surface of a conductive member, so that the cover member is engaged with the mount member so as to form the shield case,
wherein prescribed portions of the conductive member of the cover member are tightly engaged with prescribed portions of the conductive member of the mount member so as to remove the insulating films therefrom, so that the conductive member of the cover member is brought into direct contact with the conductive member of the mount member.

28. The manufacturing method for a semiconductor device according to claim 27, wherein a plurality of ground terminals, which are formed on the backside of the circuit chip, are brought into contact with the stage corresponding to the conductive member of the mount member.

29. The manufacturing method for a semiconductor device according to claim 27, wherein prescribed portions of the stage except for prescribed regions corresponding to the through holes are engaged with a plurality of recesses, which are formed and recessed from the backside of the circuit chip.
